(19) United States
(12) Patent Application Publication
(10) Pub. No.: US 2015/0021790 A1
(43) Pub. Date: Jan. 22, 2015

(54) SEMICONDUCTOR DEVICE

(71) Applicants: San Disk Corporation, Milpitas, CA (US); KABUSHIKI KAISHA TOSHIBA, Minato-ku (JP)

(72) Inventors: Satoshi NAGASHIMA, Yokkaichi-shi (JP); Atsushi SHIMODA, Yokkaichi-shi (JP); Naoyuki IIDA, Yokkaichi-shi (JP)

(73) Assignees: San Disk Corporation, Milpitas, CA (US); KABUSHIKI KAISHA TOSHIBA, Minato-ku (JP)

(21) Appl. No.: 14/200,819

(22) Filed: Mar. 7, 2014

(30) Foreign Application Priority Data
Jul. 22, 2013 (JP) 2013-152037

(51) Int. Cl. H01L 23/538

(52) U.S. Cl. CPC H01L 23/5386
USPC 257/775

(57) ABSTRACT

According to one embodiment, a semiconductor device includes a first conductive line and a second conductive line including a first extension region in which the first conductive line and the second conductive line extend in a first direction, and a bend region in which the first conductive line and the second conductive line bend with respect to the first direction, a first dummy pattern and a second dummy pattern arranged on extension regions beyond the bend region of the first conductive line and the second conductive line, respectively, in the first direction, a first contact pad and a second contact pad formed beyond the bend region in the first direction, and connected to the first conductive line and the second conductive line, respectively.

### CROSS-REFERENCE TO RELATED APPLICATIONS

This application is based upon and claims the benefit of priority from the prior Japanese Patent Application No. 2013-152037, filed Jul. 22, 2013, the entire contents of which are incorporated herein by reference.

### FIELD

Embodiments described herein relate generally to a semiconductor device.

### BACKGROUND

As the micropatterning of semiconductor elements advances, the resolution at which interconnections of the semiconductor elements are exposed has reached its limit. Therefore, a multi-patterning method capable of obtaining a line-and-space (L/S) pattern having a dimension smaller than the limit dimension of the exposure resolution is attracting attention.

Unfortunately, a processing change difference of dry etching is large in a bend region of a line-and-space pattern. This increases the line dimension in the bend region. As a consequence, adjacent lines may contact each other.

### BRIEF DESCRIPTION OF THE DRAWING

FIG. 1 is an example of a plan view showing a shortcircuit and approach of adjacent lines;

FIG. 2 is an example of a plan view showing a basic idea;

FIG. 3A is an example of a view showing a line pattern of a comparative example;

FIG. 3B is an example of a plan view showing a line pattern of an embodiment;

FIG. 4 is an example of a plan view showing the size of the line pattern of the embodiment;

FIG. 5 is an example of a conceptual view of quadruple spacer processing;

FIG. 6 is an example of a plan view showing a manufacturing method of the first embodiment;

FIG. 7 is an example of a sectional view taken along a line VII-VII in FIG. 6;

FIG. 8 is an example of a sectional view taken along a line VIII-VIII in FIG. 6;

FIG. 9 is an example of a plan view showing the manufacturing method of the first embodiment;

FIG. 10 is an example of a sectional view taken along a line X-X in FIG. 9;

FIG. 11 is an example of a sectional view taken along a line XI-XI in FIG. 9;

FIG. 12 is an example of a plan view showing the manufacturing method of the first embodiment;

FIG. 13 is an example of a sectional view taken along a line XIII-XIII in FIG. 12;

FIG. 14 is an example of a sectional view taken along a line XIV-XIV in FIG. 12;

FIG. 15 is an example of a plan view showing the manufacturing method of the first embodiment;

FIG. 16 is an example of a sectional view taken along a line XVI-XVI in FIG. 15;

FIG. 17 is an example of a sectional view taken along a line XVII-XVII in FIG. 15;

FIG. 18 is an example of a plan view showing the manufacturing method of the first embodiment;

FIG. 19 is an example of a sectional view taken along a line XIX-XIX in FIG. 18;

FIG. 20 is an example of a sectional view taken along a line XX-XX in FIG. 18;

FIG. 21 is an example of a sectional view taken along a line XXI-XXI in FIG. 18;

FIG. 22 is an example of a plan view showing the manufacturing method of the first embodiment;

FIG. 23 is an example of a sectional view taken along a line XXIII-XXIII in FIG. 22;

FIG. 24 is an example of a sectional view taken along a line XXIV-XXIV in FIG. 22;

FIG. 25 is an example of a sectional view taken along a line XXV-XXV in FIG. 22;

FIG. 26 is an example of a plan view showing the manufacturing method of the first embodiment;

FIG. 27 is an example of a sectional view taken along a line XXVII-XXVII in FIG. 26;

FIG. 28 is an example of a sectional view taken along a line XXVIII-XXVIII in FIG. 26;

FIG. 29 is an example of a sectional view taken along a line XXIX-XXIX in FIG. 26;

FIG. 30 is an example of a plan view showing the manufacturing method of the first embodiment;

FIG. 31 is an example of a sectional view taken along a line XXXI-XXXI in FIG. 30;

FIG. 32 is an example of a sectional view taken along a line XXXII-XXXII in FIG. 30;

FIG. 33 is an example of a sectional view taken along a line XXXIII-XXXIII in FIG. 30;

FIG. 34 is an example of a plan view showing the manufacturing method of the first embodiment;

FIG. 35 is an example of a sectional view taken along a line XXXV-XXXV in FIG. 34;

FIG. 36 is an example of a sectional view taken along a line XXXVI-XXXVI in FIG. 34;

FIG. 37 is an example of a sectional view taken along a line XXXVII-XXXVII in FIG. 34;

FIG. 38 is an example of a plan view showing the manufacturing method of the first embodiment;

FIG. 39 is an example of a sectional view taken along a line XXXIX-XXXIX in FIG. 38;

FIG. 40 is an example of a sectional view taken along a line XL-XL in FIG. 38;

FIG. 41 is an example of a sectional view taken along a line XLI-XLI in FIG. 38;

FIG. 42 is an example of a plan view showing the manufacturing method of the first embodiment;

FIG. 43 is an example of a sectional view taken along a line XLIII-XLIII in FIG. 42;

FIG. 44 is an example of a sectional view taken along a line XLIV-XLIV in FIG. 42;

FIG. 45 is an example of a sectional view taken along a line XLV-XLV in FIG. 42;

FIG. 46 is an example of a plan view showing the manufacturing method of the first embodiment;

FIG. 47 is an example of a sectional view taken along a line XLVII-XLVII in FIG. 46;

FIG. 48 is an example of a sectional view taken along a line XLVIII-XLVIII in FIG. 46;

FIG. 49 is an example of a sectional view taken along a line XLIX-XLIX in FIG. 46;

FIG. 50 is an example of a sectional view taken along a line L-L in FIG. 46;

FIG. 51 is an example of a plan view showing the manufacturing method of the first embodiment;

FIG. 52 is an example of a sectional view taken along a line LII-LII in FIG. 51;

FIG. 53 is an example of a sectional view taken along a line LIII-LIII in FIG. 51;

FIG. 54 is an example of a sectional view taken along a line LIV-LIV in FIG. 51;

FIG. 55 is an example of a sectional view taken along a line LV-LV in FIG. 51;

FIG. 56 is an example of a plan view showing the first example of a dummy pattern;

FIG. 57 is an example of a plan view showing the second example of the dummy pattern;

FIG. 58 is an example of a plan view showing the third example of the dummy pattern;

FIG. 59 is an example of a plan view showing the fourth example of the dummy pattern;

FIG. 60-63 are examples of views each showing a line pattern in a word line extraction region;

FIG. 64 is an example of a view showing a NAND flash memory as an application example; and

FIG. 65 is an example of a view showing a NAND block.

### DETAILED DESCRIPTION

In general, according to one embodiment, a semiconductor device includes a first conductive line and a second conductive line including a first extension region in which the first conductive line and the second conductive line extend in a first direction, and a bend region in which the first conductive line and the second conductive line bend with respect to the first direction, a first dummy pattern and a second dummy pattern arranged on extension regions beyond the bend region of the first conductive line and the second conductive line extending to the first direction in the first extension region, respectively, in the first direction, a first contact pad and a second contact pad formed beyond the bend region in the first direction, and connected to the first conductive line and the second conductive line, respectively.

Embodiments will be explained below with reference to the accompanying drawing.

### [Basic Concept]

In the multi-patterning method, a width/space of line-and-space pattern (e.g., a word line or bit line) can be smaller than the limit length of the exposure resolution by performing sidewall layer formation and transfer steps a plurality of number of times.

For example, steps including sidewall layer formation and sidewall layer pattern transfer for processing an underlayer form one cycle, and a line-and-space pattern is formed by repeating this cycle n times (n is an integer of 1 or more). A sidewall layer formed for the (n−1)th time functions as a mask layer (spacer) for forming the nth sidewall. That is, a pattern corresponding to the sidewall formed for the nth time is a line pattern (e.g., a word line).

Each of line-and-space patterns formed by performing the sidewall layer formation/transfer steps a plurality of number of times (n times) has, e.g., a line pattern (line width) smaller than the limit length of the exposure resolution, and a space pattern (line space) smaller than the limit length of the exposure resolution.

When a line-and-space pattern smaller than the limit length of the exposure resolution is formed by using multi-patterning, a space of the line becomes very narrow. Therefore, the deposited product of dry etching sometimes redeposits on the sidewall layer of a line, thereby thickening the line (increasing the line dimension). Then, the space of the line may disappear (the lines shortcircuit) and approach. The difference between the width of a mask material before processing and the line width after processing is performed to the end is called a processing conversion difference.

One of proposes of reducing the processing conversion difference is “suppressing redeposition” to lines at dry etching.

The amount of redeposition to lines tends to increase as the etching area of dry etching increases.

Especially in a bend region where adjacent lines bend in opposite directions, the amount of redeposition often increases because the etching area at dry etching in the bend region is larger than the etching area at dry etching in an extension region where adjacent lines extend at a predetermined space. This increases the processing conversion difference of lines. Therefore, probability of shortcircuit and approach of adjacent lines may become high.

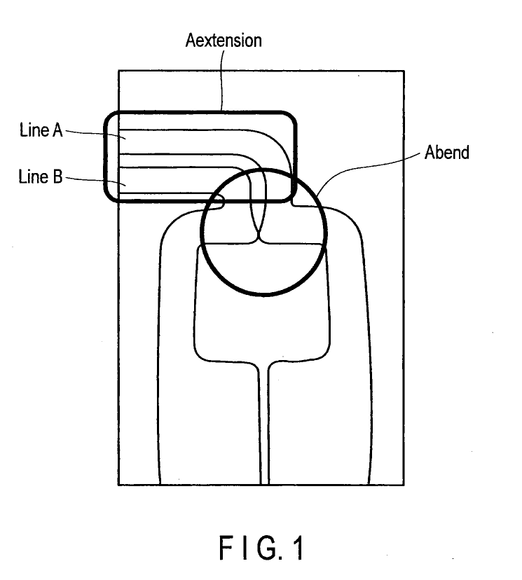

FIG. 1 is an example of a plan view showing a shortcircuit and approach of adjacent lines.

Assume that a region where adjacent lines A and B bend in opposite directions is a bend region Abend, and a region wherein the adjacent lines extend parallel to each other is an extension region (line-and-space region; L/S region) Aextension.

In the extension region (L/S region) Aextension, the space between the adjacent lines is narrow, so the deposited product of RIE hardly redeposits on the surfaces of the lines. Accordingly, the processing conversion difference is small, and a width of the lines is hardly thick.

On the other hand, in the bend region Abend, the space between the adjacent lines is wide, so the deposited product of RIE readily redeposits on the surfaces of the lines. Therefore, the processing conversion difference is large, and a width of the lines is easily thick.

In the bend region Abend, therefore, the processing conversion difference of dry etching increases, so the space between the adjacent lines becomes narrow, and shortcircuit and approach of the adjacent lines occur.

The etching area can be reduced by forming dummy patterns near the bend region Abend. When using the multi-patterning method, however, the formation of dummy patterns is difficult, so it is difficult to form dummy patterns near the bend region Abend. The formation of dummy patterns is particularly difficult when using spacer processing twice or more.

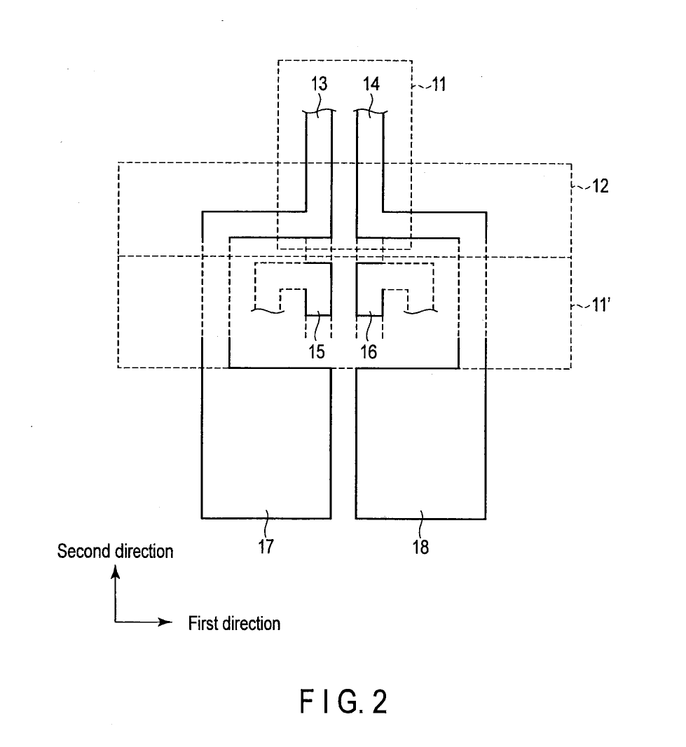

By contrast, the present inventors have found a method capable of forming dummy patterns as shown in FIG. 2 when, e.g., using spacer processing twice, thereby preventing a shortcircuit and approach of adjacent lines.

FIG. 2 is an example of a plan view showing the basic idea. FIG. 2 shows a line pattern.

This line pattern includes an extension region 11 (Aextension) where first and second conductive lines 13 and 14 extend parallel to each other, and a bend region 12 (Abend) where the first and second conductive lines 13 and 14 bend in opposite directions at one end of the extension region 11. The “opposite directions” herein mentioned mean positive and negative directions in a first direction, and include an arrangement in which lines are plane symmetry in a second direction. For example, the conductive lines 13 and 14 bend in opposite directions in the first direction.

Also, first and second dummy patterns 15 and 16 exist on extensions of the first and second conductive lines 13 and 14 in the extension region 11 in at least the second direction. The shapes of the first and second dummy patterns 15 and 16 are not particularly limited. Furthermore, at least a portion of the first dummy pattern 15 is formed on the extension region beyond the bend region 12 of the first conductive line 13 extending to the second direction in the extension region 11. Likewise, at least a portion of the second dummy pattern 16 is formed on the extension region beyond the bend region 12 of the second conductive line 14 extending to the second direction in the extension region 11.

A first contact pad 17 is connected to the first conductive line 13. A second contact pad 18 is connected to the second conductive line 14. The contact pads 17 and 18 have a width larger than that of the first and second conductive lines 13 and 14.

In this arrangement, the first and second dummy patterns 15 and 16 are formed, so no wide etching region is produced on the extension region beyond the bend region 12 of the first and second conductive lines 13 and 14 extending to the second direction in the extension region 11.

That is, the line-and-space pattern in the extension region 11 is practically maintained beyond the bend region 12.

This makes it possible to prevent a shortcircuit and approach of adjacent lines when they are processed.

Note that the first and second conductive lines 13 and 14 bend in opposite directions in the bend region 12, and the bending angle desirably is 90° or more with respect to the first and second conductive lines 13 and 14 in the extension region 11.

Note also that the first and second dummy patterns 15 and 16 may also be in contact with each other. Furthermore, each of the first and second dummy patterns 15 and 16 has a first portion extending in the second direction and formed on the extension region of a corresponding one of the first and second conductive lines 13 and 14 extending to the second direction in the first extension region, a second portion having one end in contact with the first portion and extending in the first direction, and a third portion having one end in contact with the second portion and extending in the second direction. The second portions are formed parallel to the first and second conductive lines 13 and 14 in the bend region 12, and the third portions are formed parallel to the first and second conductive lines 13 and 14 in an extension region 11′.

The shapes of the first and second dummy patterns 15 and 16 will be described later.

Also, it is preferable that the first and second dummy patterns 15 and 16 are arranged to be symmetrical (plane symmetry) in the first direction from the viewpoint of a lithography margin.

Furthermore, the positions and shapes of the first and second contact pads 17 and 18 are not particularly restricted.

For example, the first and second contact pads 17 and 18 may or may not be in contact with the first and second dummy patterns 15 and 16, provided that the first and second contact pads 17 and 18 are not electrically connected.

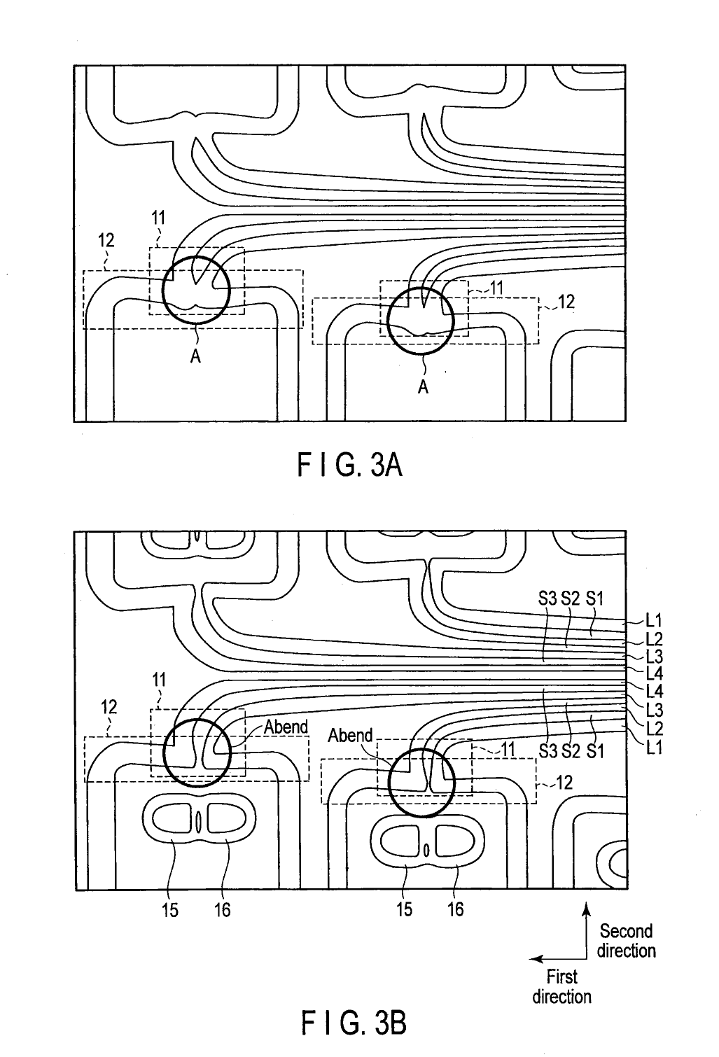

FIG. 3A shows an example of a simulation result of a line pattern of a comparative example.

FIG. 3B shows an example of a simulation result of a line pattern of an embodiment.

FIGS. 3A and 3B illustrate simulations results obtained by using an in-house simulator. FIG. 3B reveals that when dummy patterns are formed near the bend region 12, the processing conversion difference between lines is reduced during dry etching, and it is possible to prevent a shortcircuit and approach of adjacent lines at the multi-patterning method.

Also, when two-time spacer processing is used and line patterns L1, L2, L3, and L4 are formed from the outside in a line-and-space pattern portion, the line widths often satisfy L1>L2>L3>L4. Likewise, when two-time spacer processing is used and spaces S1, S2, and S3 are formed between the line patterns from the outside in the line-and-space pattern portion, the space widths often satisfy S1>S2>S3.

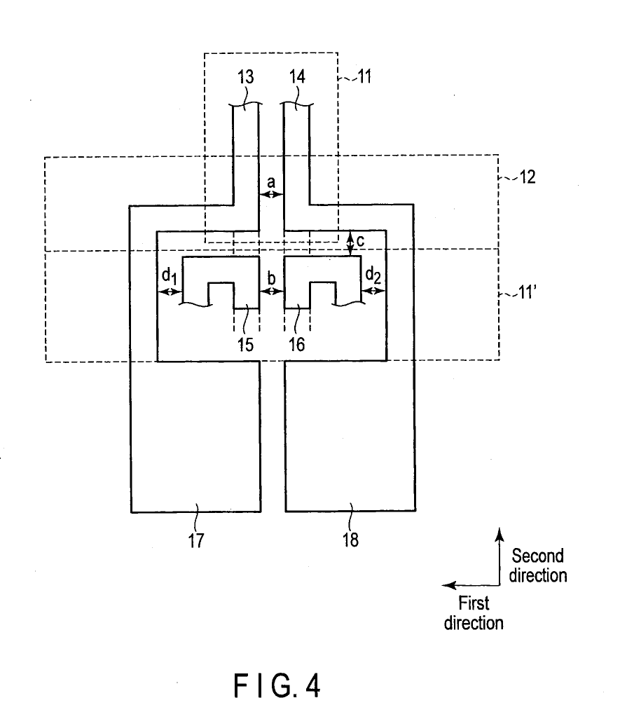

FIG. 4 is an example of a plan view showing the size of the line pattern in the embodiment.

A space a between the first and second conductive lines 13 and 14 in the extension region 11 and a space b between the first and second dummy patterns 15 and 16 desirably have almost the same width (a=b). The “extension region 11” herein mentioned is, in the second direction in FIG. 4, a portion above the position at which the first and second conductive lines 13 and 14 bend in the first direction.

In the bend region 12, the first and second conductive lines 13 and 14 bend in opposite directions in the first direction. A space c between the pair of the first and second conductive lines 13 and 14 in the bend region 12 and the pair of the first and second dummy patterns 15 and 16 can be a width at which the first and second dummy patterns 15 and 16 are not in contact with the first and second conductive lines 13 and 14 in the bend region 12 (c>0).

The first and second conductive lines 13 and 14 further have the extension region 11′ where these lines bend in the second direction and extend parallel to each other. In the extension region 11′, each of the first and second conductive lines 13 and 14 is connected to one end, on a side opposite to the extension region 11 side, of a corresponding one of the first and second conductive lines 13 and 14 in the bend region 12.

A distance d₁ between the first conductive line 13 in the extension region 11′ and first dummy pattern 15 and a distance d₂ between the second conductive line 14 in the extension region 11′ and second dummy pattern 16 are desirably 100 nm or less (d₁, d₂≦100 nm).

A embodiment will be explained below.

### Embodiment

This embodiment is an example in which the basic concept is applied to a hook-up region, i.e., a portion where a contact is connected to a word line.

In this embodiment, two-time spacer processing is used as the multi-patterning method.

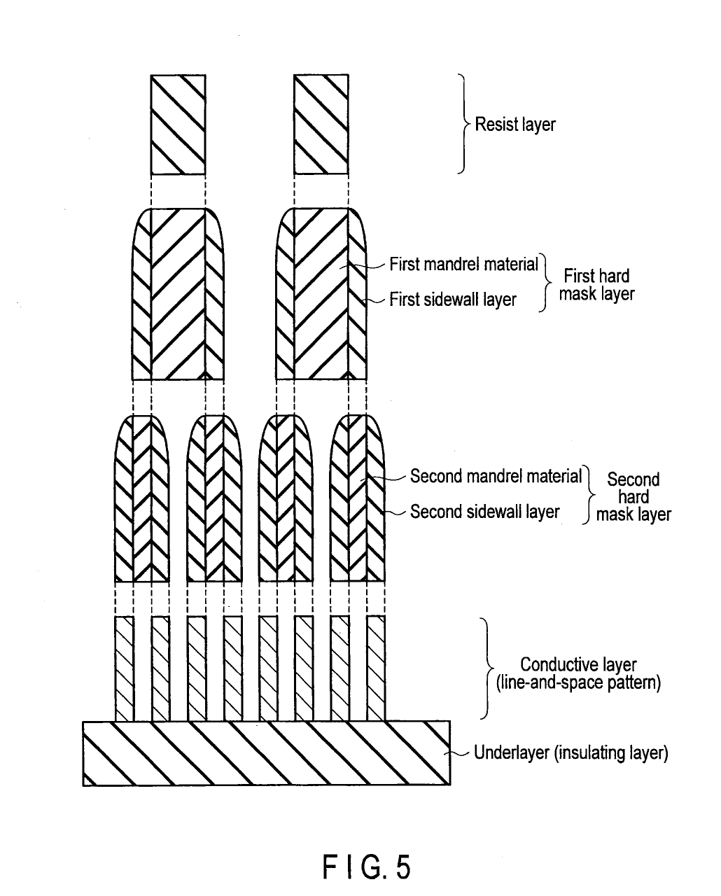

FIG. 5 is an example of a conceptual view of two-time spacer processing.

A multilayered structure of two-time spacer processing includes an underlayer, a conductive layer on the underlayer, a second hard mask layer on the conductive layer, a first hard mask layer on the second hard mask layer, and a resist layer on the first hard mask layer.

The underlayer is an insulating layer, and the conductive layer is formed into a line-and-space pattern by two-time spacer processing.

The first hard mask layer includes a first mandrel material, and a first sidewall layer formed on the sidewall layer of the first mandrel material.

The second hard mask layer includes a second mandrel material, and a second sidewall layer formed on the sidewall layer of the second mandrel material.

First, the first mandrel material is patterned by performing first lithography by using the resist layer as a mask.

Then, first sidewall layers (sidewalls) are formed on the side surfaces of the first mandrel material. In this step, two first sidewall layers are formed for one first mandrel material (a double spacer).

The second mandrel material is patterned by performing second lithography by using the first sidewall layers as masks.

Second sidewall layers are formed on the side surfaces of the second mandrel material. In this step, two second sidewall layers are formed for one second mandrel material. That is, four second sidewall layers are formed for one first mandrel material.

Finally, the conductive layer is patterned by performing third lithography by using the second sidewall layers as masks.

As described above, two-time spacer processing is a technique of processing an interconnection layer by using four sidewall layers formed from one first mandrel material (resist layer).

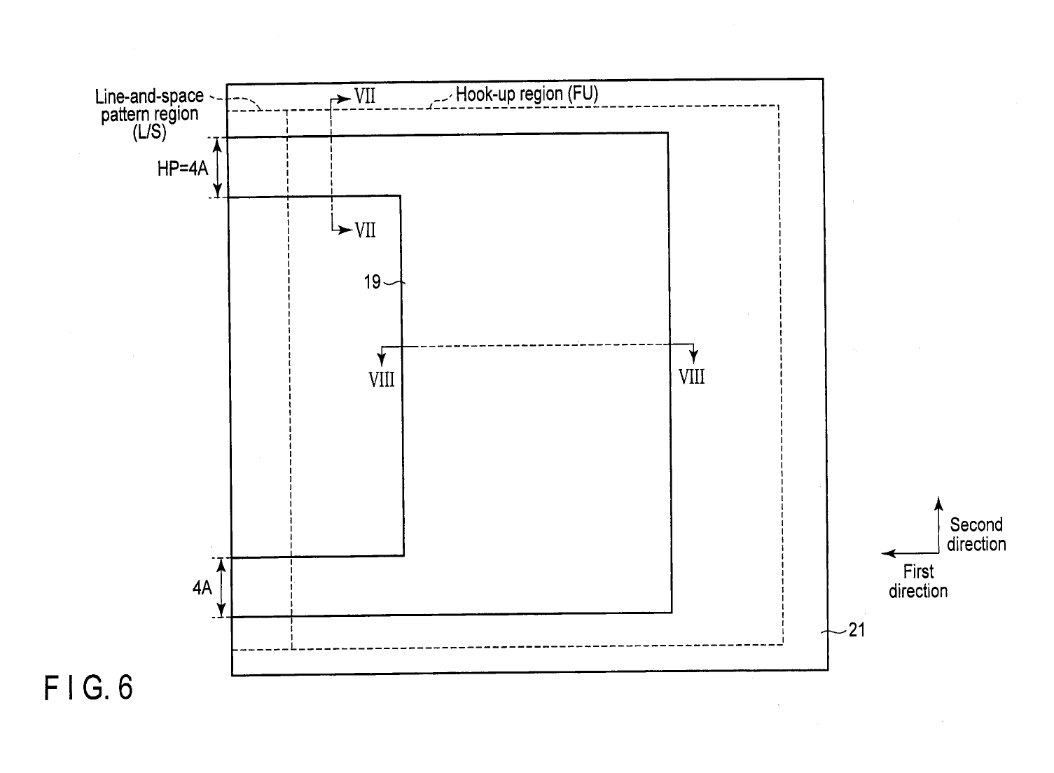

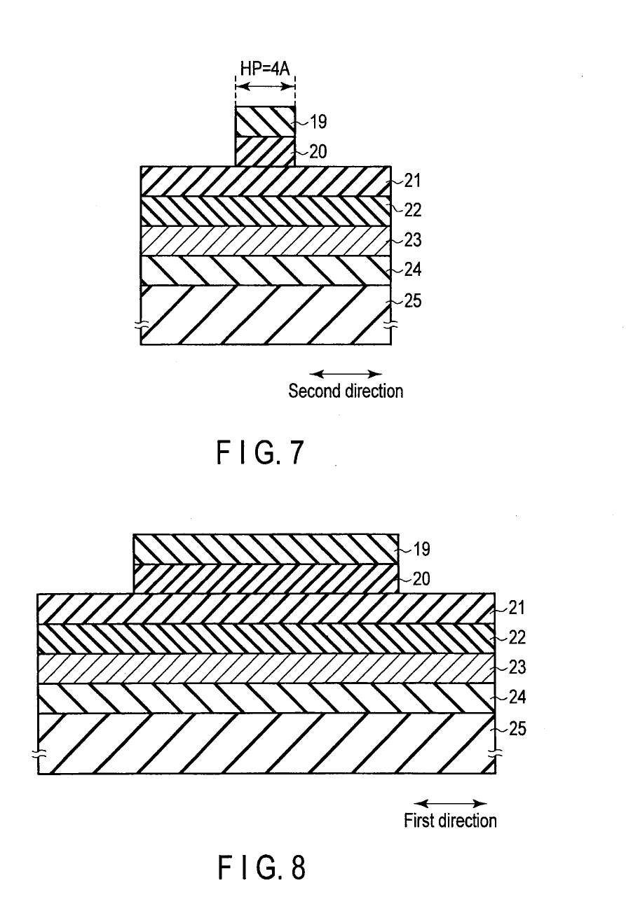

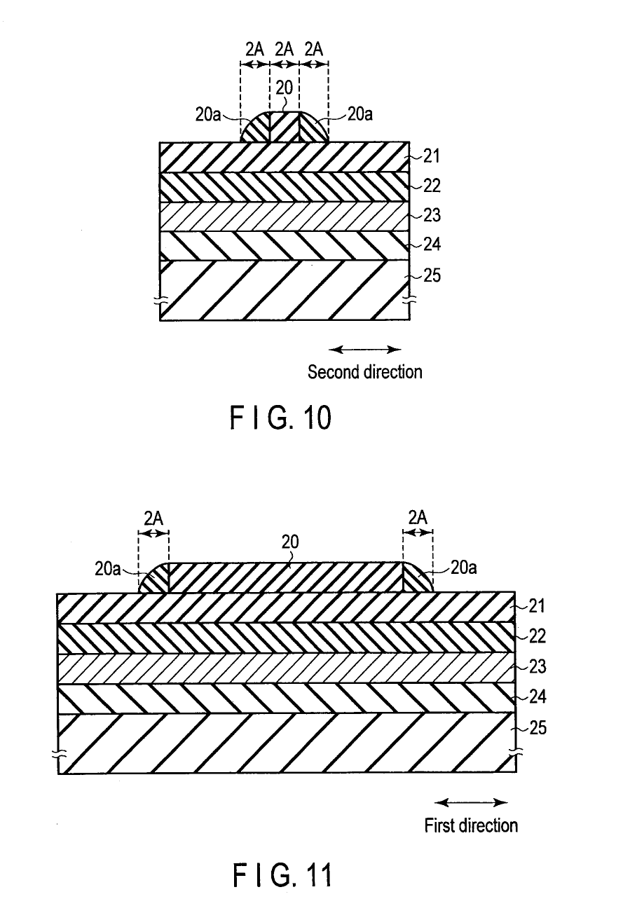

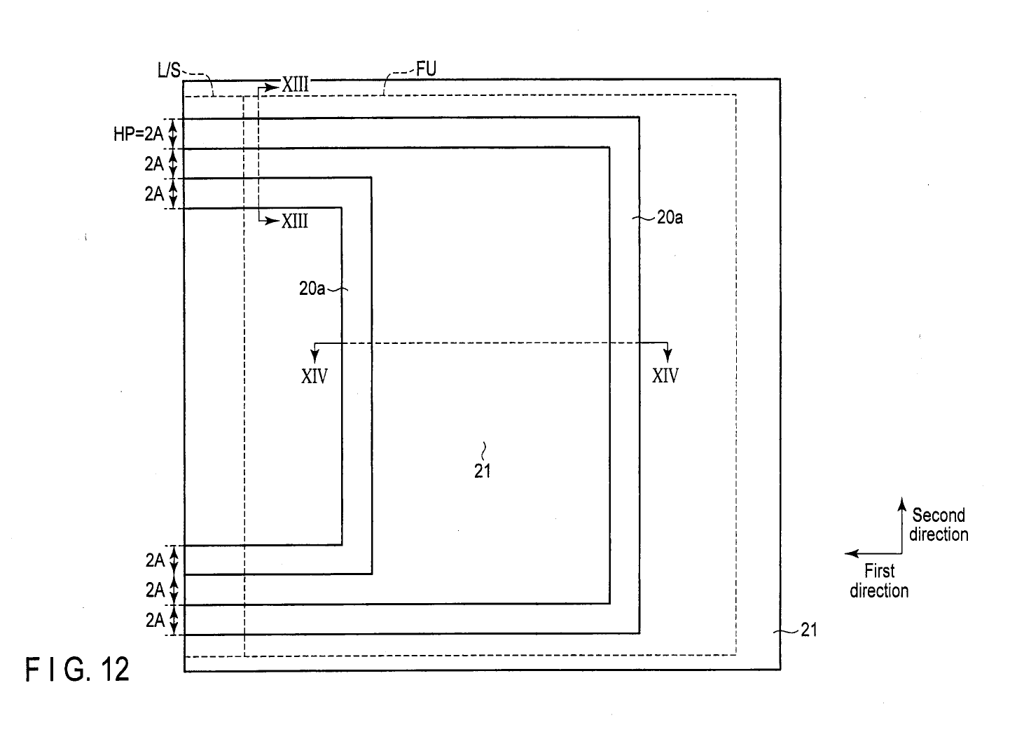

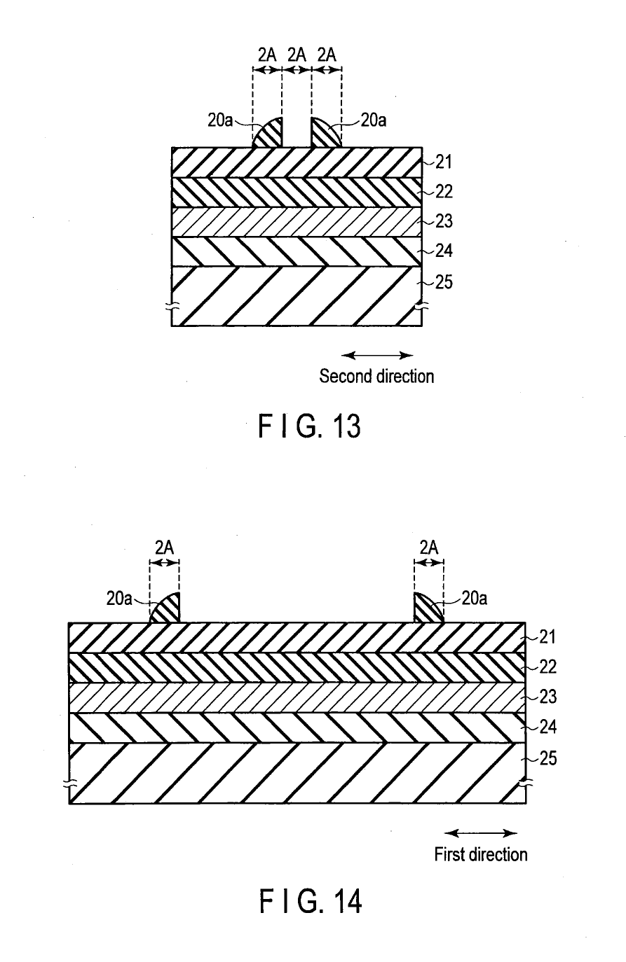

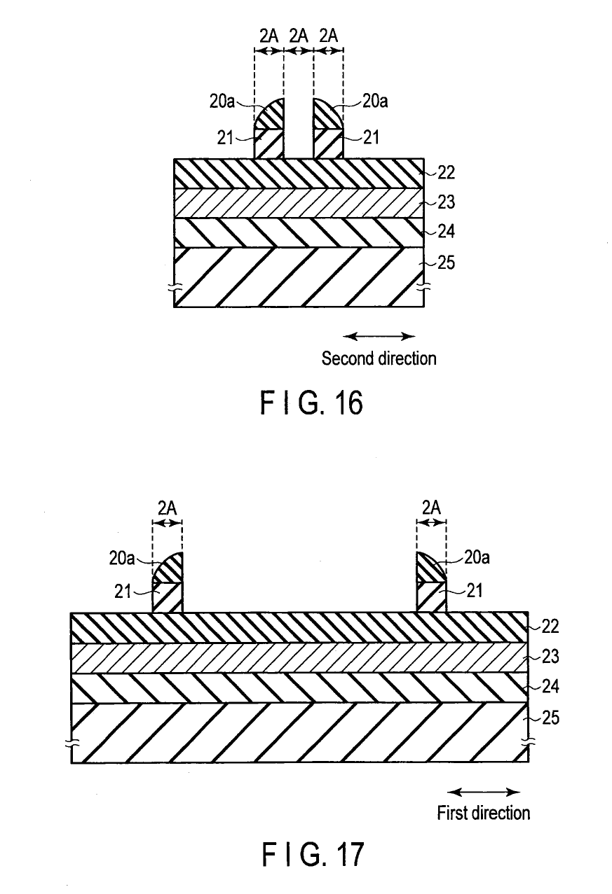

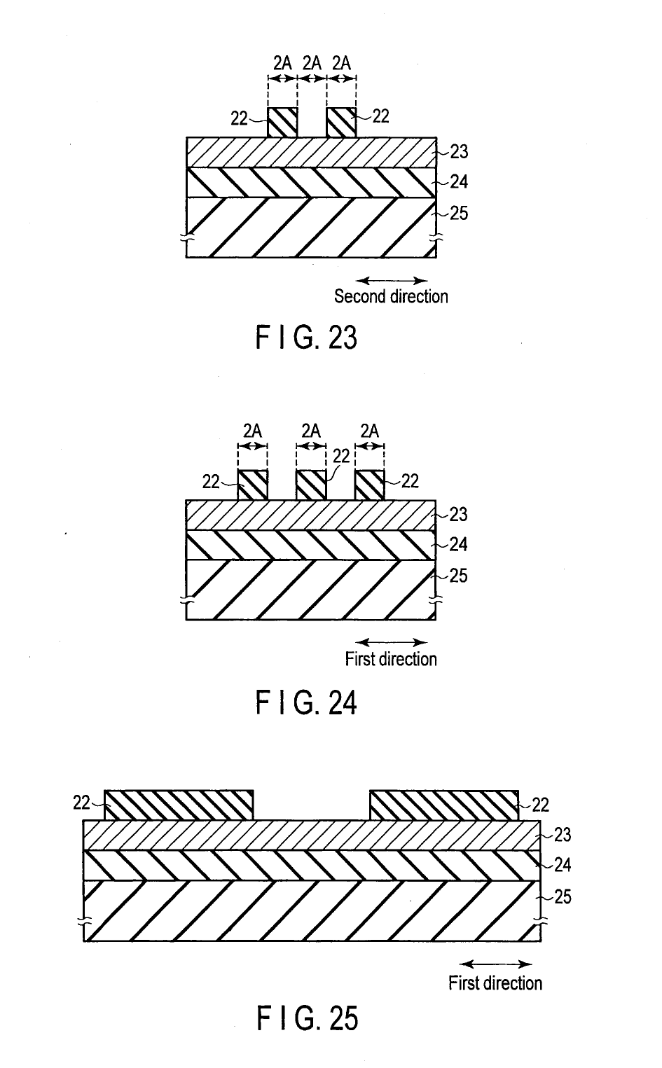

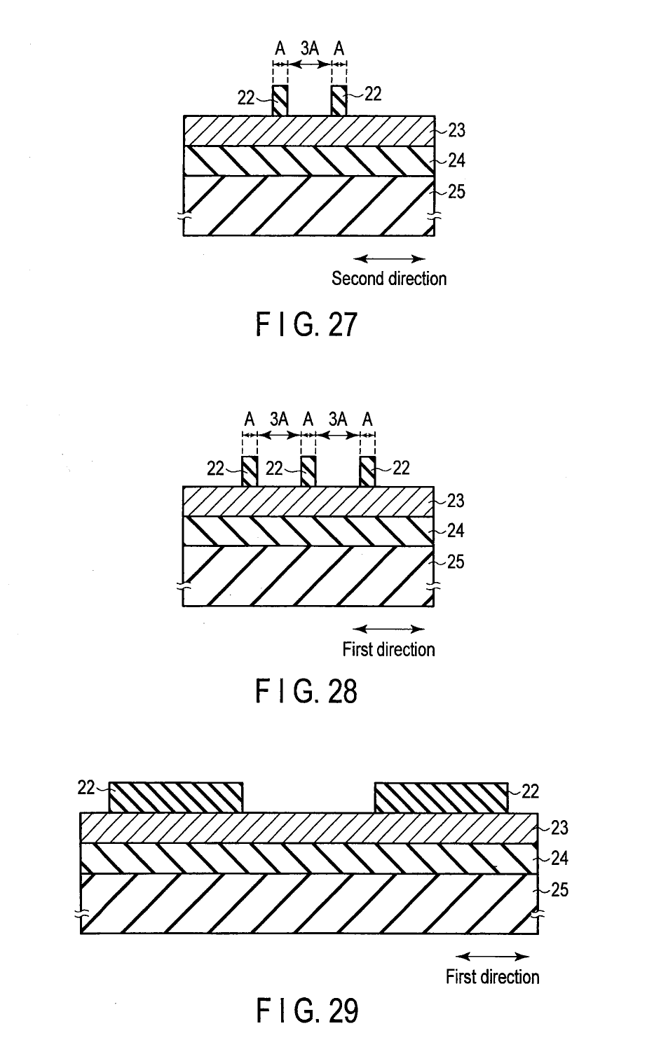

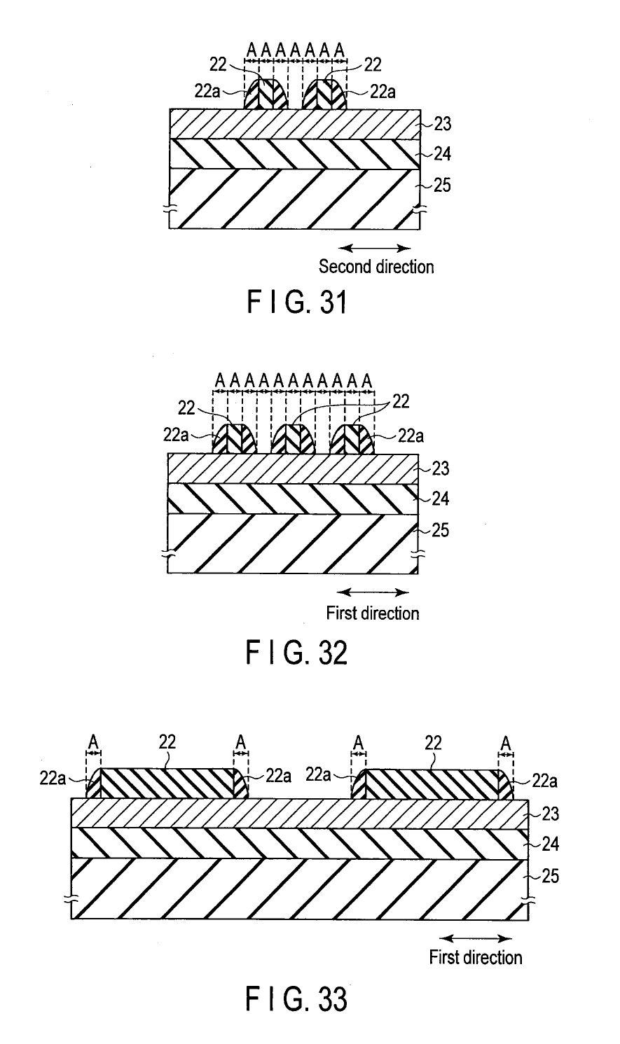

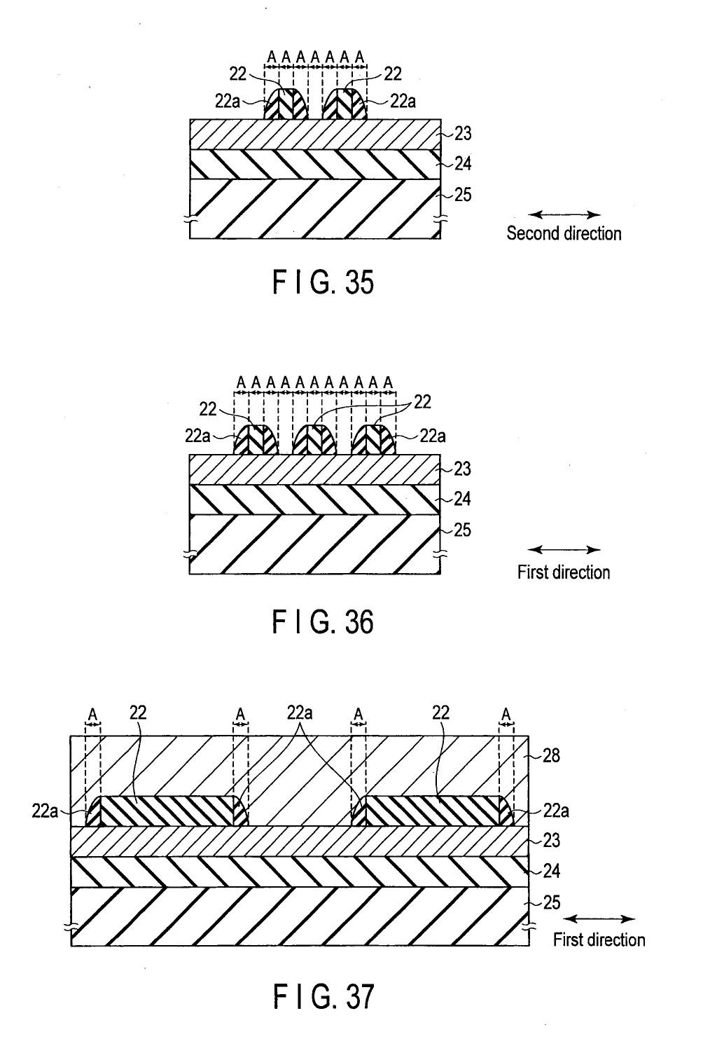

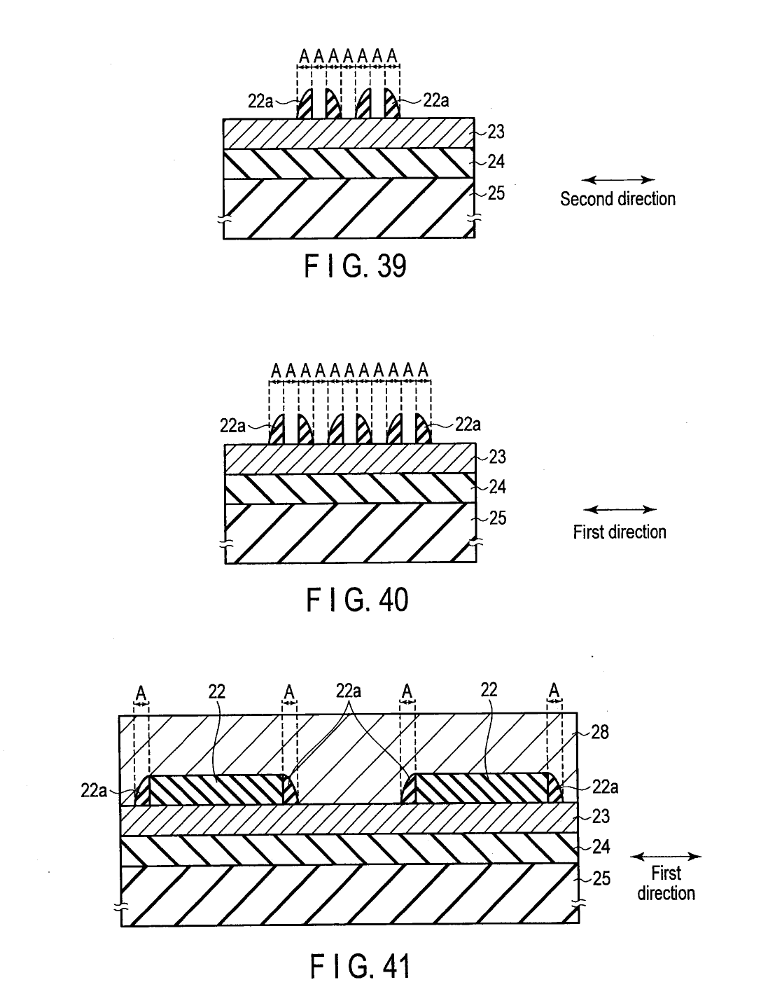

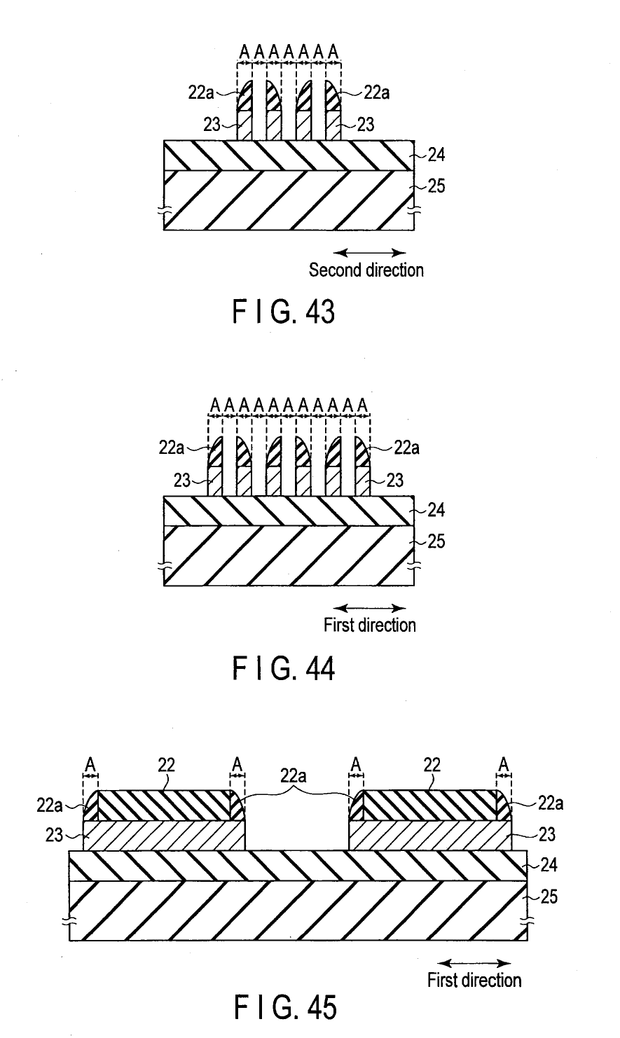

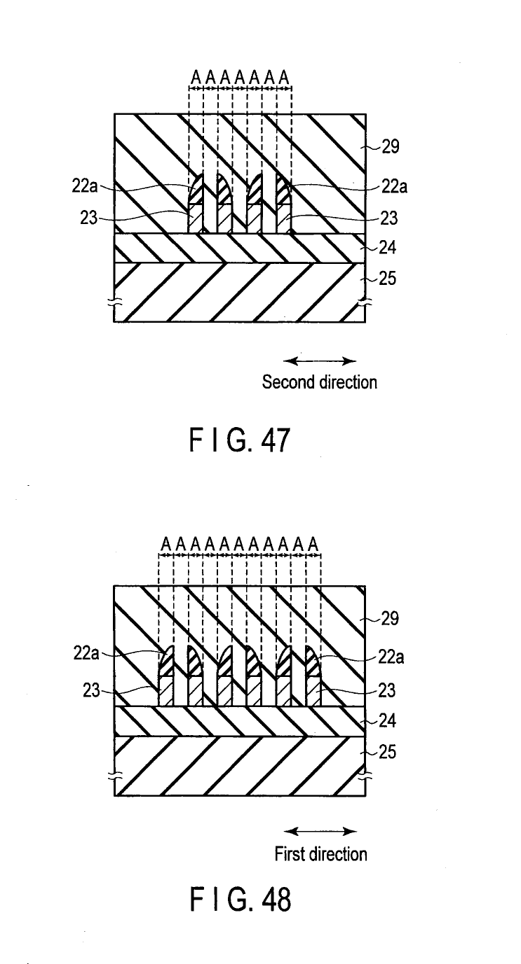

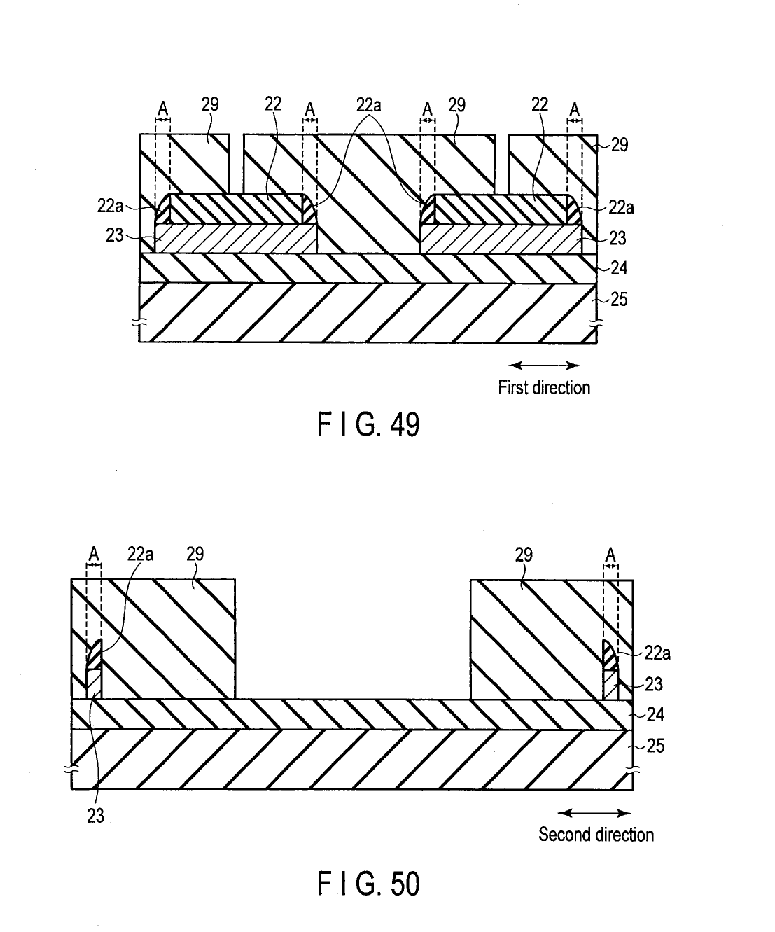

Next, a method of forming a hook-up region (FU) will be explained below with reference to FIGS. 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, and 55. First, as shown in FIGS. 6, 7, and 8, an insulating layer 24 is formed on a semiconductor substrate 25, a conductive layer 23 is formed above the insulating layer 24, a second mandrel material 22 is formed on the conductive layer 23, a hard mask layer 21 is formed on the second mandrel material 22, a first mandrel material 20 is formed on the hard mask layer 21, and a first resist layer 19 is formed on the first mandrel material 20.

The first resist layer 19 is formed by a predetermined line-and-space pattern in a line-and-space pattern region (L/S). The first resist layer 19 is extracted to a hook-up region (FU), and two first resist layers 19 are connected in the hook-up region.

Assuming that the final half pitch (HP) of a line to be formed in the line-and-space pattern region (L/S) by two-time spacer processing is A [nm]. As shown in FIG. 6, therefore, the half pitch HP in the second direction of the first resist layer 19 in the line-and-space pattern region (L/S) is 4A.

Then, the first mandrel material 20 is patterned (transferred) by anisotropic dry etching (e.g., reactive ion etching) by using the first resist layer 19 as a mask. The first mandrel material is, e.g., an oxide layer or organic layer.

After that, the first resist layer 19 is removed by ashing.

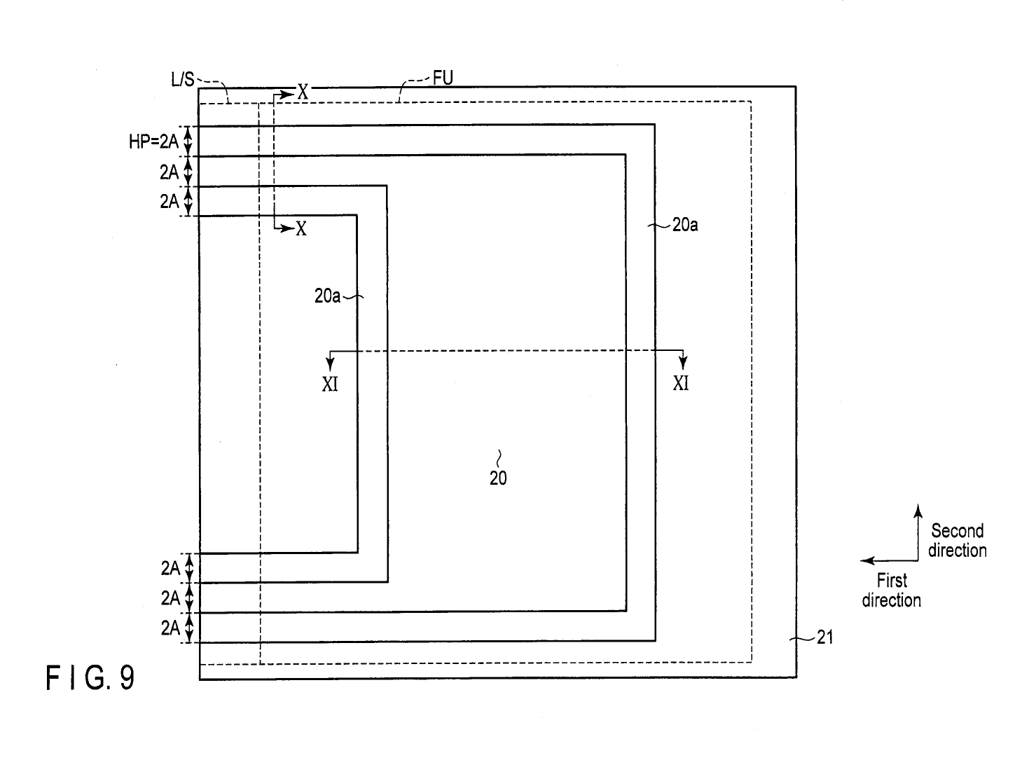

The first mandrel material 20 is slimmed as shown in FIGS. 9, 10, and 11.

By this slimming, the width in the second direction of the first mandrel material 20 in the line-and-space pattern region (L/S) reduces from 4A to 2A. That is, the sidewall layers of the first mandrel material 20 in the line-and-space pattern region (L/S) are slimmed to A [nm] on one side (2A [nm] on two sides).

When the first mandrel material 20 is an oxide layer, slimming may be performed by wet etching using hydrogen fluoride HF or dry etching (CDE or RIE). When the first mandrel material 20 is an organic layer, slimming can be performed by RIE or O₂ or O₃ plasma etching.

Then, first sidewall layers 20a are formed on the sidewall layers of the first mandrel material 20. That is, the first sidewall layers 20a are processed (etched back or planarized) into a spacer shape by, e.g., CVD and RIE.

The width in the second direction of the first sidewall layers 20a in the line-and-space pattern region (L/S) is 2A.

When the first mandrel material 20 is, e.g., an oxide layer, the first sidewall layers 20a are amorphous silicon layers, polysilicon layers, or silicon nitride layers. When the first mandrel material 20 is an organic layer, the first sidewall layers 20a are low-temperature oxide layers or low-temperature nitride layers.

Then, the first mandrel material 20 is selectively removed as shown in FIGS. 12, 13, and 14. When the first mandrel material 20 is removed, the hard mask layer 21 as an underlayer of the first mandrel material 20 is exposed.

Also, when the first mandrel material 20 is removed, the first sidewalls 20a form lines having a width of 2A [nm]. That is, a line-and-space pattern having a width of 2A [nm] is formed in the second direction in the line-and-space pattern region (L/S). The width of the first sidewall layers 20a in the first direction in the hook-up region (FU) is 2A [nm].

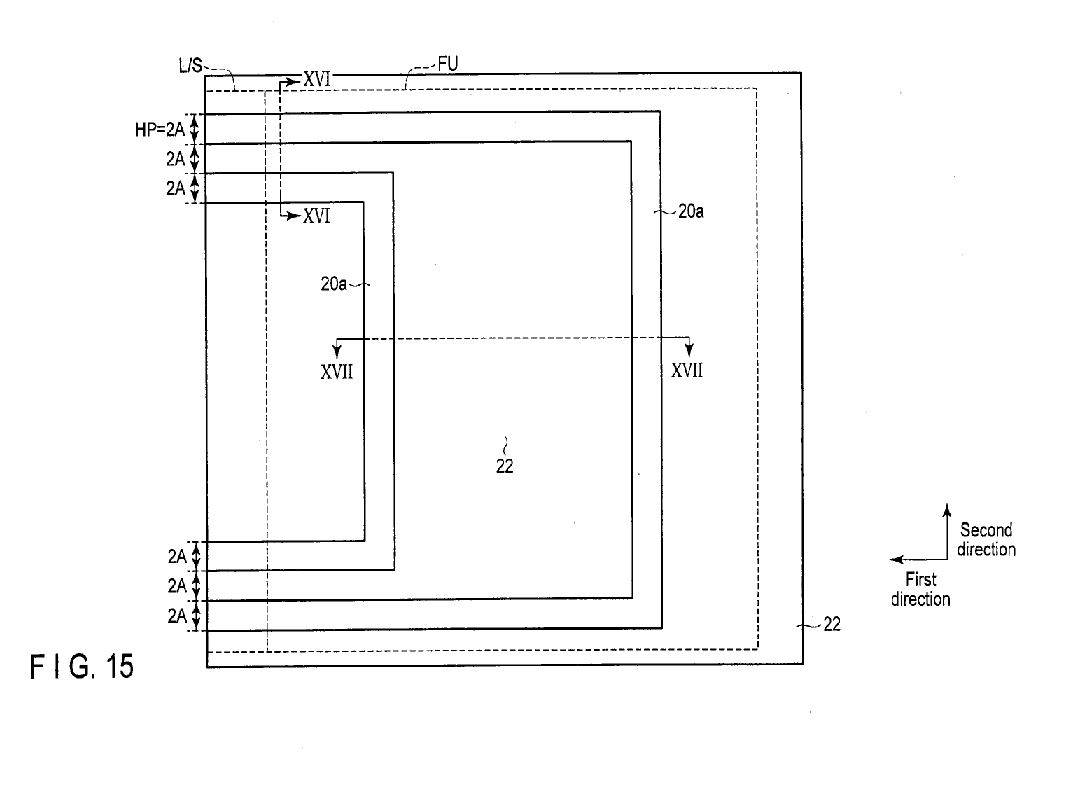

When the first mandrel material 20 is an oxide layer, examples of the method of removing the first mandrel material 20 are wet etching using HF, CDE (Chemical Dry Etching), and RIE. When the first mandrel material 20 is an organic layer, examples of the removing method are wet etching using SPM washing and ashing. Then, as shown in FIGS. 15, 16, and 17, the pattern is transferred to the hard mask layer 21 by RIE by using the first sidewall layers 20a as spacers (masks).

As the hard mask layer 21, a material with which an etching selectively is obtained for the first mandrel material 20 is used.

For example, the hard mask layer 21 is a nitride layer when the first mandrel material 20 is an oxide layer and the first sidewall layer 20a is an amorphous silicon layer or polysilicon layer. Also, the hard mask layer 21 is an amorphous silicon layer or polysilicon layer when the first mandrel material 20 is an oxide layer and the first sidewall layer 20a is a nitride layer. Furthermore, the hard mask layer 21 is an amorphous silicon layer, polysilicon layer, or nitride layer when the first mandrel material 20 is an organic layer and the first sidewall layer 20a is a low-temperature oxide layer or low-temperature nitride layer.

The second mandrel material 22 as an underlayer of the hard mask layer 21 is exposed when the hard mask layer 21 is processed.

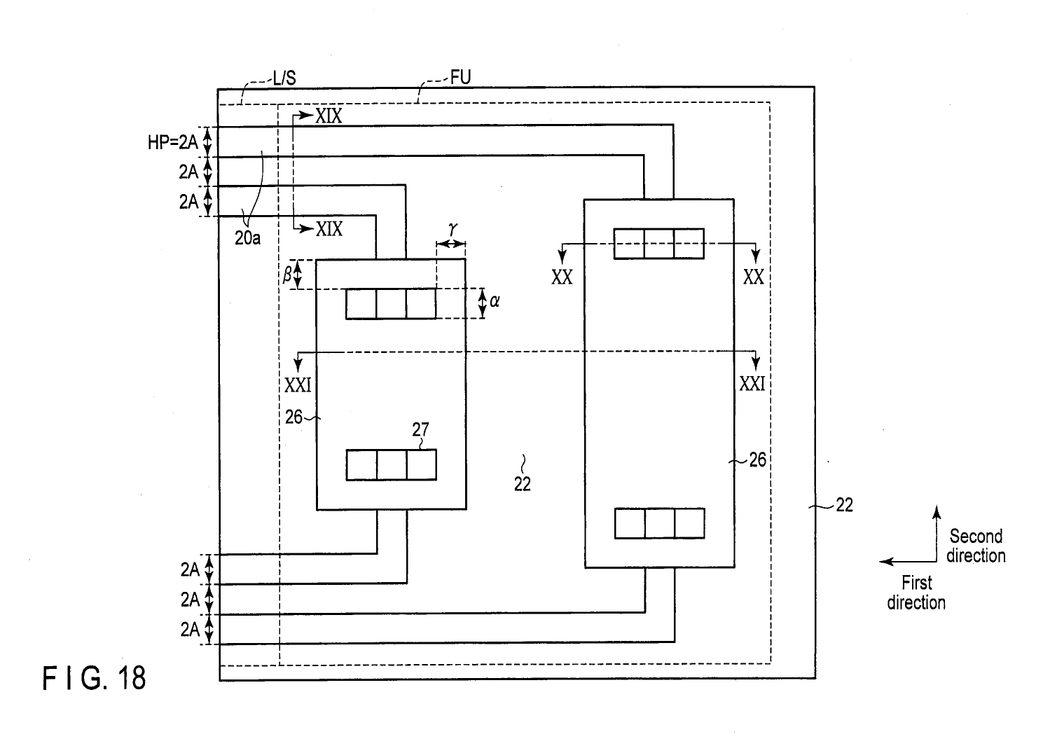

Then, as shown in FIGS. 18, 19, 20, and 21, second resist layers 26 are formed in a prospective dummy pattern/contact pad region in the hook-up region (FU).

Assume that the prospective dummy pattern/contact pad region in the hook-up region (FU) is a contact pad region. Note that the contact pad region includes a contact pad and its periphery.

In this contact pad region, the second resist layers 26 are so formed as to cover the second mandrel material in the contact pad region, and cover the hard mask 21 and first sidewall layers 20a extending in the second direction in the contact pad region.

In addition, the second resist layer 26 has a first opening 27 across the first sidewall layers 20a in a prospective dummy pattern region in the contact pad region. A plurality of first openings 27 may also be formed in the contact pad region.

The first sidewall layer 20a extending in the first opening 27 is not coated with the second resist layer 26.

That is, the first sidewall layer 20a is exposed in the first opening 27.

Also, the lengths of a short side α and remaining widths β and γ of the first opening 27 are preferably as small as possible. These values are preferably the minimum exposure length of an exposure apparatus to be used when forming the second resist layers 26.

When using a general ArF dry exposure apparatus, the minimum dimensions are 100≦α≦200 nm, and β, γ=about 100 nm. When using an exposure technique having a higher accuracy such as an ArF liquid immersion exposure apparatus, EUV exposure apparatus, or NIL (Nano Imprint Lithography) apparatus, the dimensions of α, β, and γ further decrease.

If, however, the dimensions of β and γ are 100 nm or more, it may be impossible to form the first opening 27. That is, it may be impossible to suppress redeposition, and suppress a shortcircuit and approach of adjacent lines. Therefore, assuming that the exposure limit of the ArF dry exposure apparatus is an upper limit, 0≦α≦200 nm and 0<β, γ<about 100 nm.

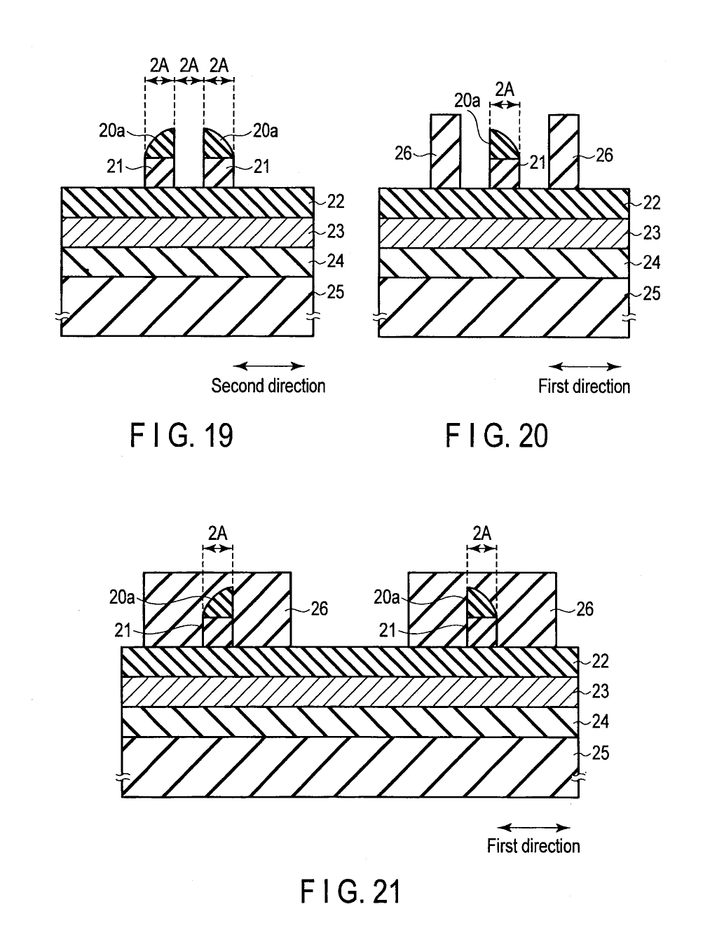

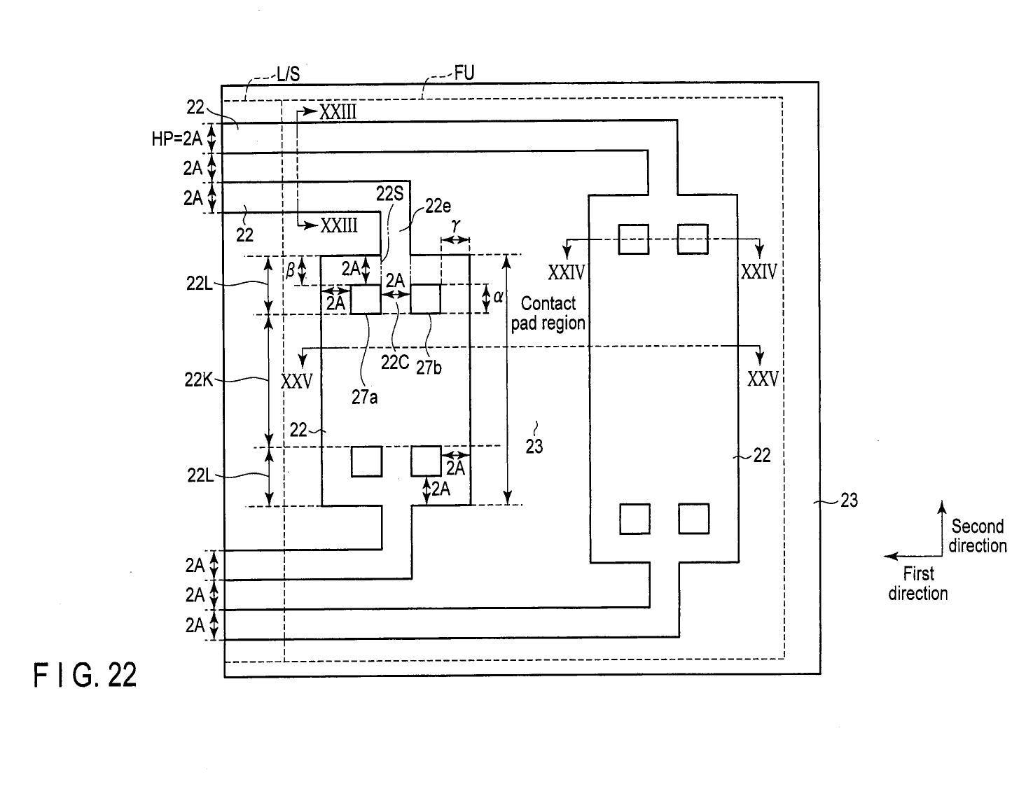

Then, as shown in FIGS. 22, 23, 24, and 25, the second mandrel material 22 is patterned by using the second resist layer 26 and a multilayered structure including the hard mask layer 21 and first sidewall layer 20a shown in FIG. 19 as masks. When the second mandrel material 22 is patterned, the conductive layer 23 as an underlayer of the second mandrel material 22 is exposed in the line-and-space pattern region (L/S) and hook-up region (FU).

The multilayered structure including the hard mask layer 21 and first sidewall layer 20a is selectively removed by using wet etching or RIE after this patterning. For example, when the hard mask layer 21 is a nitride layer, hot-H₃PO₄ is used in wet etching. When the hard mask layer 21 is a silicon layer, wet etching using a strong alkali such as KOH or TMAH, CDE, RIE, or the like is used.

When the second resist layer 26 and the multilayered structure including the hard mask layer 21 and first sidewall layer 20a are selectively removed from the surface of the second mandrel material 22, a second mandrel 22 having second and third openings 27a and 27b can be formed in a prospective dummy pattern region in the contact pad region.

Assume that the prospective dummy pattern region in the contact pad region is a dummy pattern region.

The second and third openings 27a and 27b are formed to be symmetrical with respect to a line pattern extending to the second direction in the center of the dummy pattern region. Also, a second mandrel material 22c is formed in the opening 27 by using the exposed hard mask 21. As a result, a side surface 22s of a second mandrel material 22e extending in the second direction from the contact pad region and a side surface 22s of the second mandrel material 22c are almost aligned in the first direction.

Note that when a plurality of first openings 27 are formed, a plurality of second openings 27a and a plurality of third openings 27b can be formed.

Thus, a line pattern and rectangular pattern are formed in the contact pad region by patterning the second mandrel material 22. Of the second mandrel material 22 in the contact pad region, a pattern having a width of 2A [nm] is called a line pattern 22L, and a pattern having a width larger than that of the line pattern is called a rectangular pattern 22K. However, the line pattern width is not limited to 2A [nm].

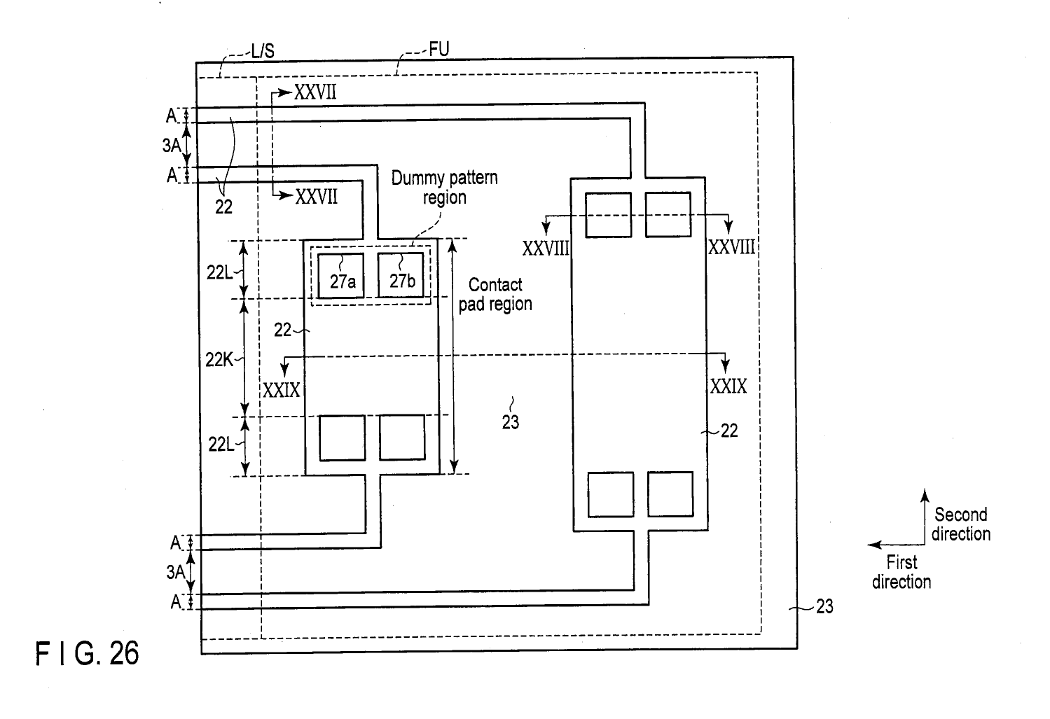

Then, the second mandrel materials 22 are slimmed as shown in FIGS. 26, 27, 28, and 29.

In this step, the sidewall layers of the second mandrel materials 22 are slimmed by a width of 0.5A [nm] on one side (a width of A [nm] on two sides).

Consequently, the width in the second direction of the second mandrel materials 22 extending in the first direction in the line-and-space pattern region (L/S) is reduced from 2A [nm] to A [nm]. That is, the space between the two second mandrel materials 22 extending in the first direction in the line-and-space pattern region (L/S) is 3A.

When the second mandrel materials 22 are oxide layers, slimming can be performed by wet etching using hydrogen fluoride HF or RIE. When the second mandrel materials 22 are organic layers, slimming can be performed by RIE or O₂ or O₃ plasma etching.

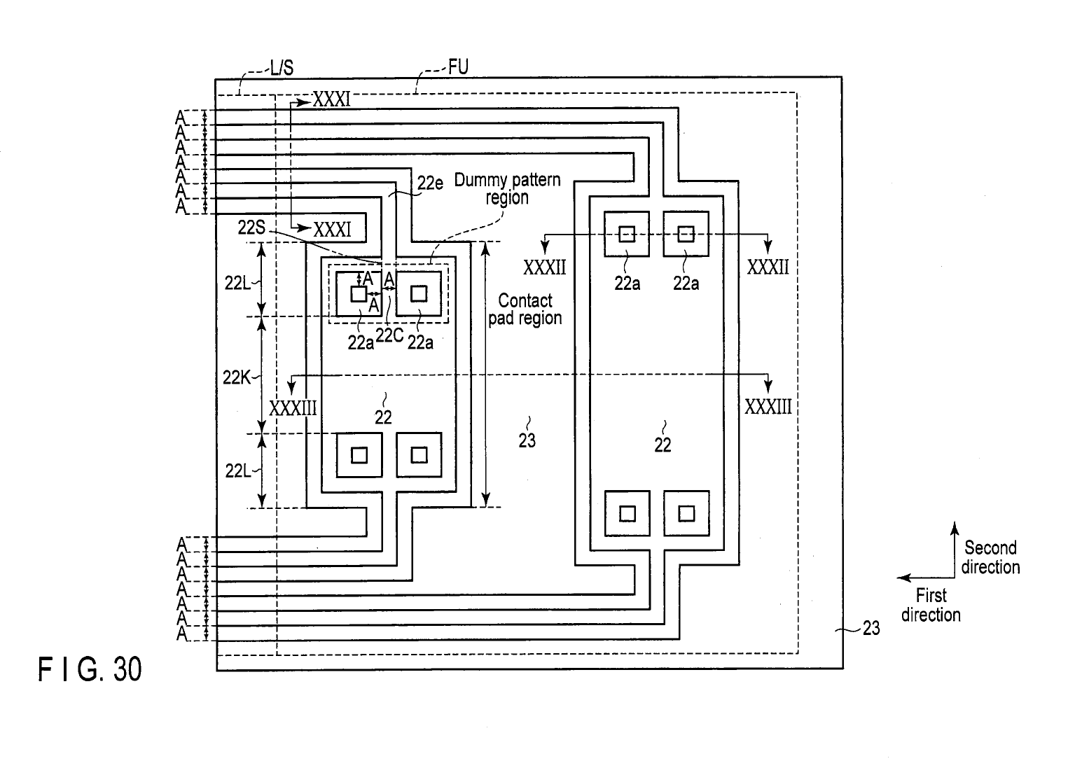

Then, as shown in FIGS. 30, 31, 32, and 33, second sidewall layers 22a having a width of A [nm] are formed on the sidewall layers of the second mandrel materials 22. The second sidewall layers 22a are processed (etched back or planarized) into a spacer shape by RIE.

Consequently, a line-and-space pattern including the second mandrel materials 22 having a width of A [nm] in the second direction and the second sidewall layers 22a and extending in the first direction can be formed in the line-and-space pattern region (L/S). The width of the second mandrel material 22c formed between the sidewall layers 22a is A [nm]. The width of the second mandrel material 22e extending in the second direction from the contact pad region is also A [nm]. Furthermore, the side surfaces 22s of the second mandrel materials 22c and 22e are almost aligned in the same position in the first direction.

When the second mandrel materials 22 are oxide layers, the second sidewall layers 22a are amorphous silicon layers, polysilicon layers, or nitride layers. When the second mandrel materials 22 are organic layers, the second sidewall layers 22a are low-temperature oxide layers or low-temperature nitride layers.

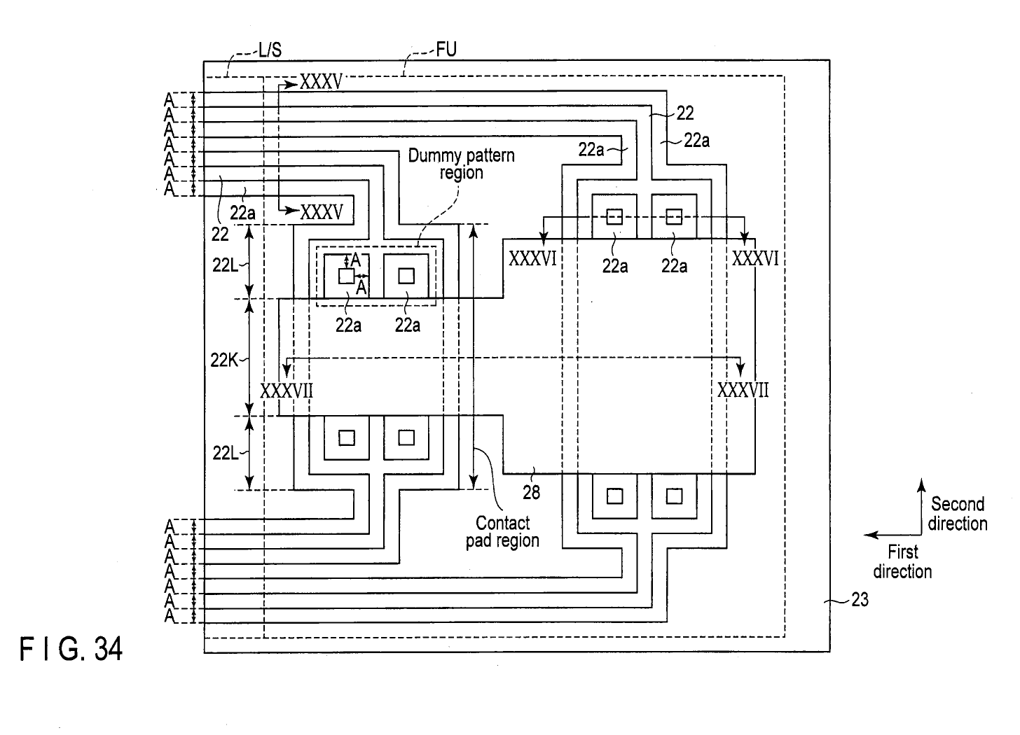

Then, as shown in FIGS. 34, 35, 36, and 37, a third resist layer 28 is so formed as to cover the rectangular pattern 22K in the contact pad region. Third resist layers 28 covering adjacent rectangular patterns 22K can also be connected.

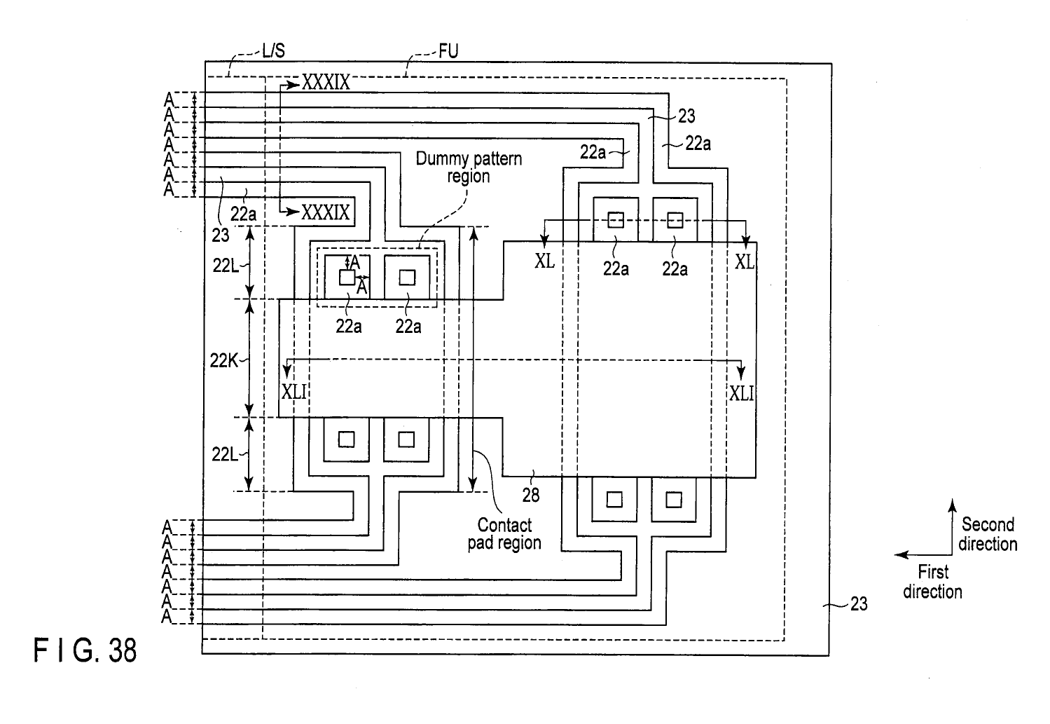

Subsequently, as shown in FIGS. 38, 39, 40, and 41, the second mandrel material 22 sandwiched between the second sidewall layers 22a is removed from a region not covered with the third resist layer 28, i.e., from a region except for the rectangular pattern 22K.

Consequently, a line-and-space pattern having a width of A [nm] in the second direction and extending in the first direction can be formed in the line-and-space pattern region (L/S). In addition, a line-and-space pattern having a width of A [nm] and extending in the first or second direction is formed in the extension region 11 and bend region 12 in the hook-up region (FU). Furthermore, a ring pattern having a width of A [nm] is formed in each of the second and third openings 27a and 27b in the dummy pattern region in the contact pad region.

The ring pattern can also be formed to be symmetrical with respect to the line pattern formed along the second direction in the center of the dummy pattern region.

When a plurality of first openings 27 are formed, a plurality of ring patterns may be formed like the second and third openings 27a and 27b.

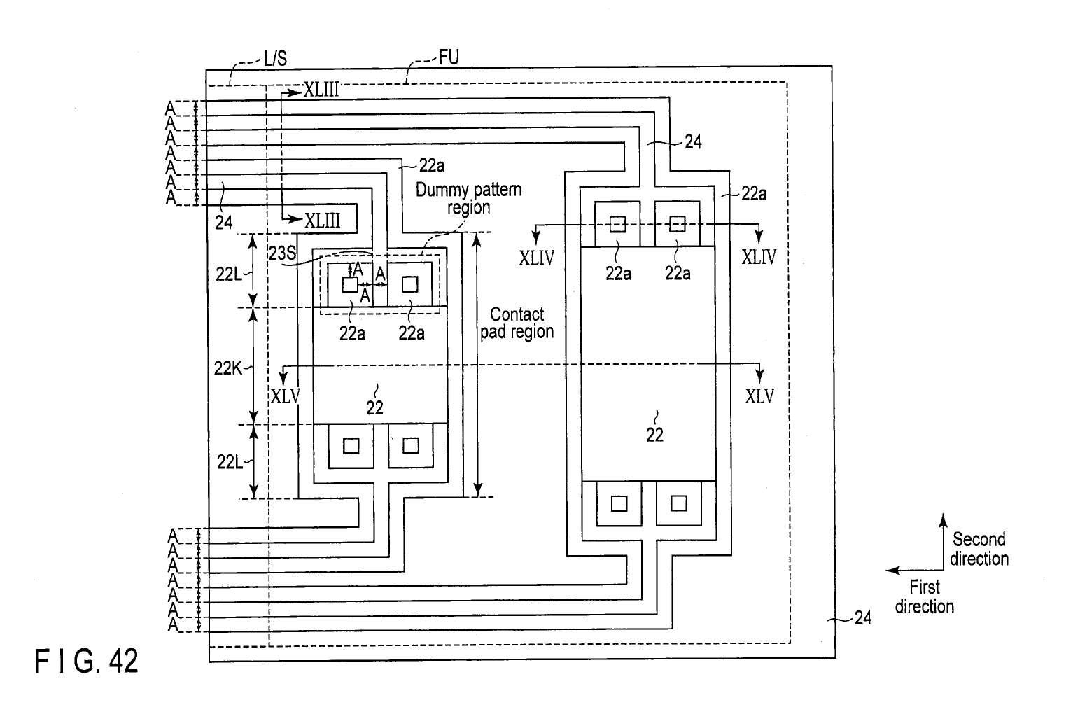

Then, as shown in FIGS. 42, 43, 44, and 45, the third resist layer 28 covering the rectangular pattern 22K is removed by ashing.

Subsequently, in the rectangular pattern 22K, the conductive layer 23 as an underlayer is processed by using the second mandrel material 22 and second sidewall patterns 22a as masks. In addition, in a region except for the rectangular pattern 22K, the conductive layer 23 as an underlayer is processed by using the second sidewall layers 22a as masks. RIE is used in this processing of the conductive layer 23. Also, the space between the ring patterns becomes A [nm]. The space between the second sidewall layers 22a extending in the second direction from the contact pad region also becomes A [nm]. The side surfaces 23s of the ring pattern and second sidewall 22a are almost aligned in the same position in the first direction.

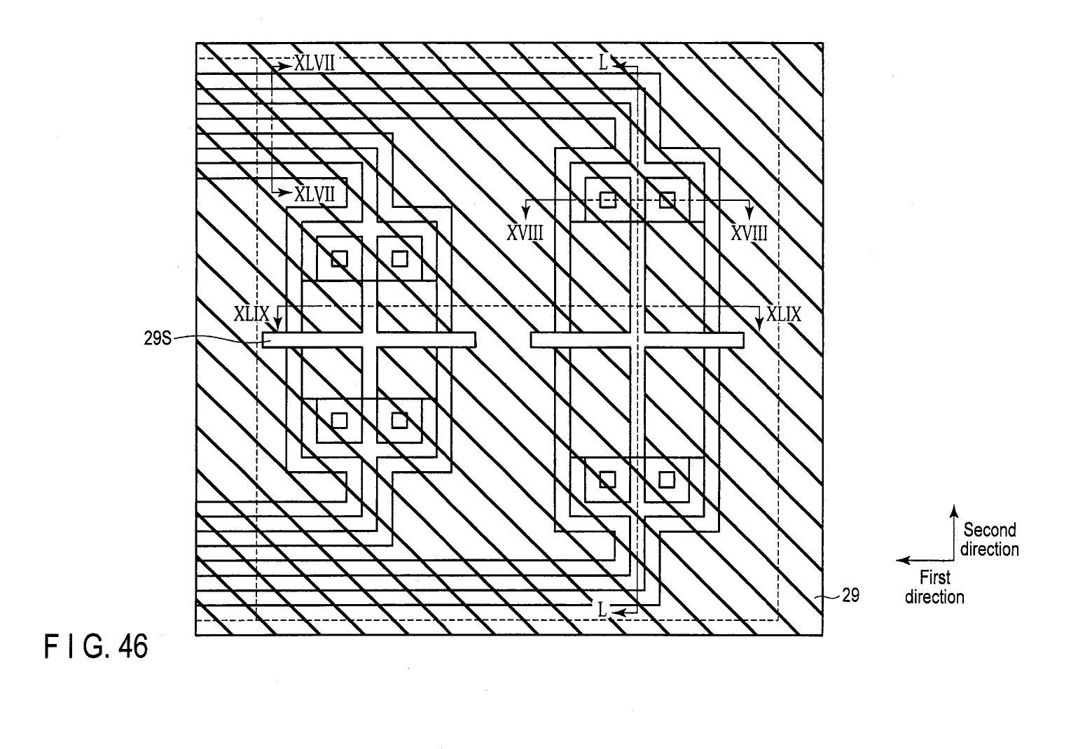

Then, as shown in FIGS. 46, 47, 48, 49, and 50, the rectangular pattern 22K is cut in order to form a plurality of contact pads in the rectangular pattern 22K.

To cut the rectangular pattern 22K, the rectangular pattern 22K is coated with a fourth resist layer 29 having a slit pattern 29S. For example, the slit pattern is a cross pattern formed along the first and second directions. The end portions of the slit pattern 29S in the second direction are almost aligned with the end portions of the rectangular pattern 22K. Also, the end portions of the slit pattern 29S in the first direction project from the second sidewall layers 22a formed on the side surfaces of the contact pad region.

By performing etching by using the fourth resist layer 29 as a mask, the second mandrel material 22 and second sidewall layers 22a in the rectangular pattern 22K are cut.

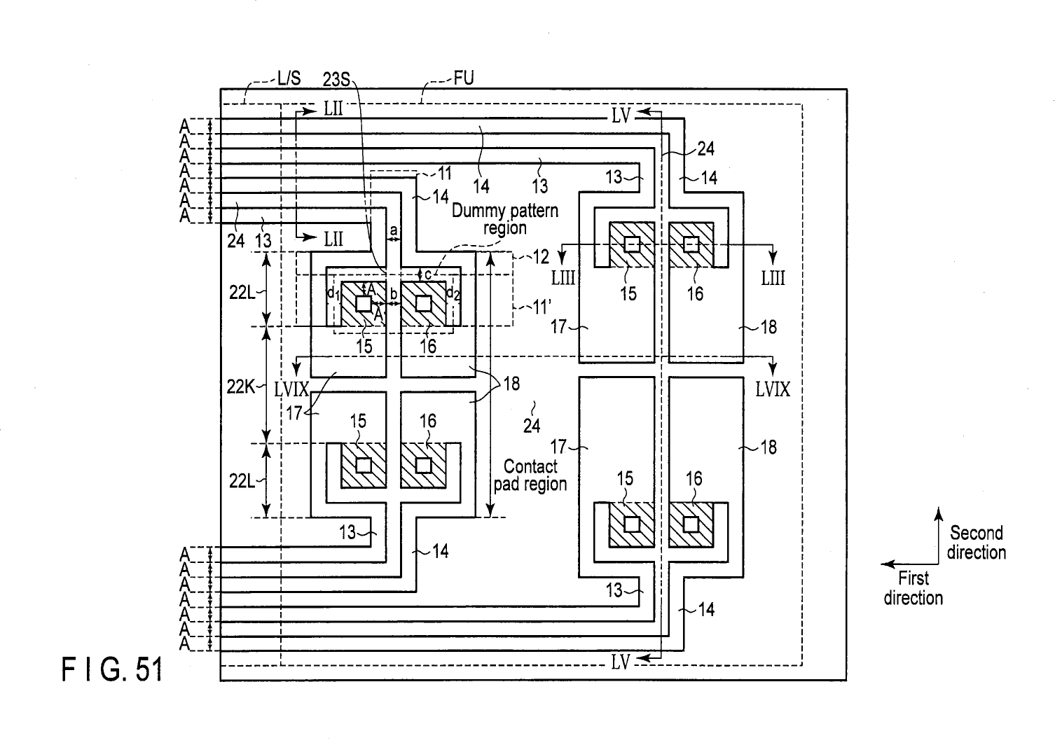

Consequently, as shown in FIG. 51, a line pattern including first and second conductive lines 13 and 14 including a first extension region 11 in which the first and second conductive lines 13 and 14 extend parallel to each other and a bend region 12 in which the first and second conductive lines 13 and 14 bend in opposite directions at one end of the first extension region 11, first and second dummy patterns 15 and 16 arranged on the side of the bend region 12 in the second direction, a first contact pad 17 connected to the first conductive line 13 in the bend region 12, and a second contact pad 18 connected to the second conductive line 14 in the bend region 12 can be formed in the hook-up region (FU). The width of the first and second conductive lines 13 and 14 is A [nm].

The space between the dummy patterns 15 and 16 is space b=A [nm]. The space between the first and second conductive lines 13 and 14 extending in the second direction from the contact pad region is also space a=A [nm]. In addition, the side surfaces 23s of the first and second conductive lines 13 and 14 and the side surfaces 23s of the dummy patterns 15 and 16 are almost aligned in the same position in the first direction.

Furthermore, in the line-and-space pattern region (L/S), the first and second conductive lines 13 and 14 have a line-and-space pattern having a width of A [nm] in the second direction and extending in the first direction.

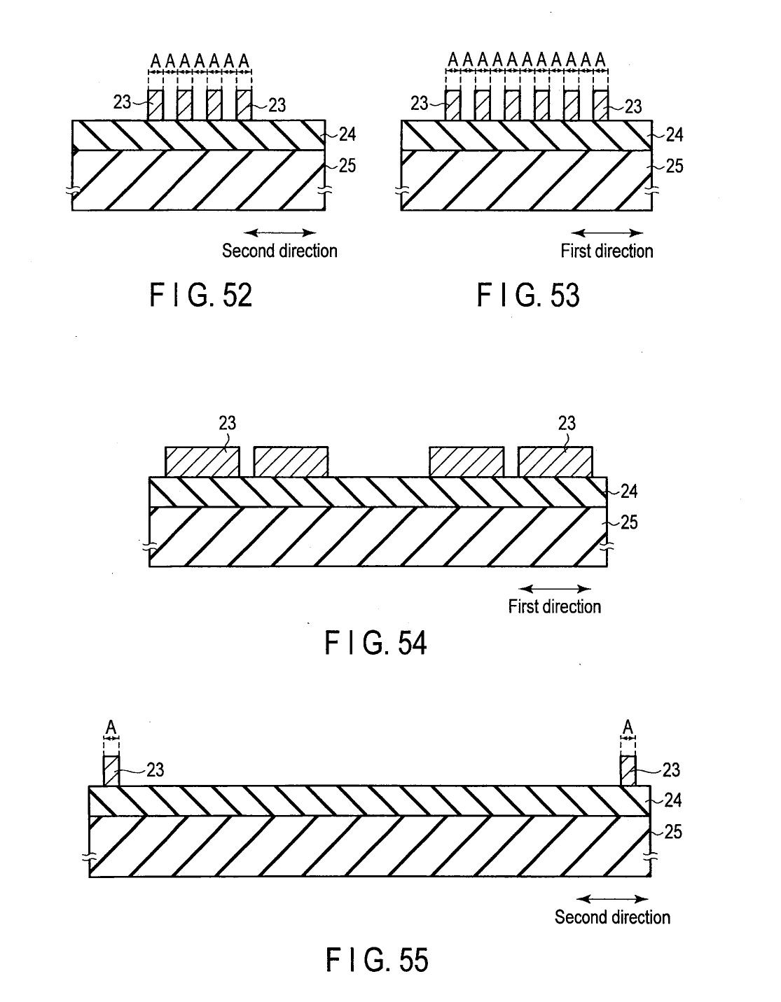

Note that as shown in FIGS. 52, 53, 54, and 55, the second mandrel material 22 and second sidewall layers 22a can also be removed after the conductive layer 23 is processed.

Note also that the shape of the first and second dummy patterns 15 and 16 is determined by the width in the second direction of the third resist layer 28 in the rectangular pattern 22K, and the slit length in the second direction of the fourth resist layer 29 in the rectangular pattern 22K. The shape of the first and second dummy patterns 15 and 16 will be explained later in modifications.

The first and second conductive lines 13 and 14 further have an extension region 11′ in which the first and second conductive lines 13 and 14 extend parallel to each other in the contact pad region. Each of the first and second conductive lines 13 and 14 in the extension region 11′ is connected to one end, on a side opposite to the side of the first extension region 11, of a corresponding one of the first and second dummy patterns 15 and 16 in the bend region 12.

Each of a distance d1 between the first conductive line 13 in the extension region 11′ and the first dummy pattern 15 (a hatched portion) and a distance d2 between the second conductive line 14 in the extension region 11′ and the second dummy pattern 16 (a hatched portion) is 100 nm or less (d1, d2≦100 nm).

The directions in which the first and second conductive lines 13 and 14 extend in the extension regions 11 and 11′ are preferably the same.

In the bend region 12, the first and second conductive lines 13 and 14 preferably bend at an angle exceeding 90°.

The first and second dummy patterns 15 and 16 are preferably symmetrically arranged.

A space a between the first and second conductive lines 13 and 14 in the first extension region 11 and a space b between the first and second dummy patterns 15 and 16 (hatched portions) are preferably equal (a=b).

The first and second contact pads 17 and 18 and the first and second dummy patterns 15 and 16 are preferably not in contact with each other (c>0).

The first and second contact pads 17 and 18 and the first and second dummy patterns 15 and 16 are not in contact with each other in some cases. In this case, the first and second dummy patterns 15 and 16 are formed in a region between the pair of the first and second conductive lines 13 and 14 and the pair of the first and second contact pads 17 and 18 in the bend region 12.

The first and second dummy patterns 15 and 16 are preferably arranged along the first and second conductive lines 13 and 14 in the bend region 12.

That is, the first and second dummy patterns 15 and 16 may also extend parallel to the first and second conductive lines 13 and 14 in the bend region 12, while a predetermined distance is held between them.

For example, as shown in FIG. 51, when the first and second conductive lines 13 and 14 in the bend region 12 bend at right angles, the first and second dummy patterns 15 and 16 preferably bend at right angles while a distance of A [nm] is held with respect to the first and second conductive lines 13 and 14 in the bend region 12. As can be understood from the plan views in FIGS. 18 and 26, the rectangular pattern 22 is formed by overlaying the first sidewall layers 20a and second resist layers 26, and the first and second conductive lines 13 and 14 are formed by using the second sidewalls 22a using the side surfaces of the rectangular pattern 22. Therefore, the processing margin is largest when the first and second dummy patterns 15 and 16 bend at right angles while a distance of A [nm] is held with respect to the first and second conductive lines 13 and 14 in the bend region 12.

Furthermore, as shown in FIG. 3B, the first and second dummy patterns 15 and 16 may also partially be in contact with each other.

When the first and second dummy patterns 15 and 16 are in contact with each other, however, the first and second dummy patterns 15 and 16 must be spaced apart from the first and second conductive lines 13 and 14.

In the first embodiment as described above, the first and second dummy patterns 15 and 16 are arranged near the bend region 12 including the first and second conductive lines 13 and 14. This prevents a deposited product of dry etching from redepositing on the surfaces of the first and second conductive lines 13 and 14 in the bend region 12, thereby preventing a shortcircuit or approach of the first and second conductive lines 13 and 14 in the bend region.

That is, even when using the multi-patterning method, dummy patterns can be arranged near a region where the pitch increases from the pitch of a line-and-space pattern to that of a line pattern. As a consequence, a deposited product of dry etching can be blocked. Even when using the multi-patterning method, therefore, it is possible to prevent a shortcircuit and approach of adjacent lines near the portion where the pitch increases.

Note that the same effect can be obtained regardless of the shape of the dummy pattern.

Examples of the dummy pattern shape are a ring pattern connected to a contact pad, e.g., a C-shape, a key-like shape such as an inverted L-shape, an ellipse, and an oblong.

The connection relationship between the dummy pattern and contact pad can be determined by the length in the second direction of the third resist layer 28 formed in the rectangular pattern 22K.

The dummy pattern shape will be explained below by taking examples.

### First Example of Dummy Pattern

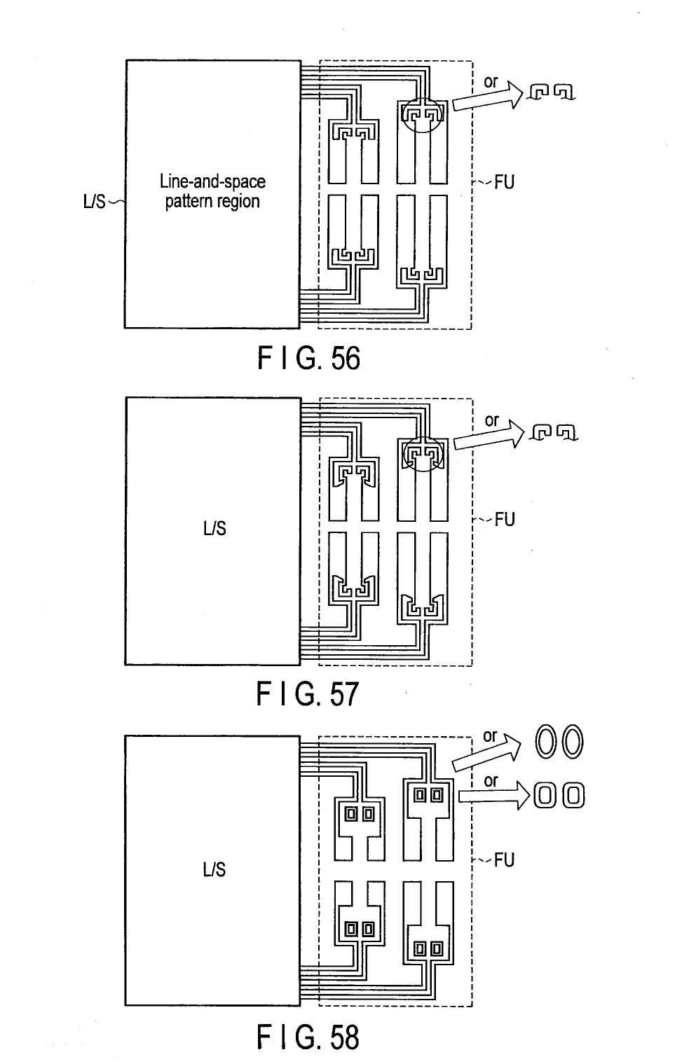

FIG. 56 is an example of a plan view showing the first example of the dummy pattern.

In this example, the contact pad and dummy pattern are in contact with each other. The shape of the dummy pattern is an oblong ring pattern and the oblong ring pattern is partially omitted. The shape of the dummy pattern can also be regarded as a semicircular shape. As shown in, e.g., FIG. 38, when bringing the third resist layer 28 in the rectangular pattern 22K into contact with the ring pattern including the second sidewalls 22a formed in the second and third openings 27a and 27b in the dummy pattern region, the second mandrel material 22 between the ring pattern and third resist layer 28 is completely covered with the third resist layer 28. In the step of removing the second mandrel material 22, therefore, the mandrel material 22 between the ring pattern and third resist layer 28 is not removed. Consequently, as shown in FIGS. 42 and 51, the dummy pattern and contact pattern are connected by the second mandrel material 22.

Furthermore, as shown in, e.g., FIG. 46, the dummy pattern can partially be omitted by exposing a portion to be cut in the ring pattern to the opening of the slit formed in the fourth resist layer 29 in the rectangular pattern 22K.

### Second Example of Dummy Pattern

FIG. 57 is an example of a plan view showing the second example of the dummy pattern.

In this example, as in the first example of the dummy pattern, the contact pad and dummy pattern are in contact with each other. The shape of the dummy pattern is an oblong ring pattern and the oblong ring pattern is partially omitted. The shape of the dummy pattern can also be regarded as a semicircular shape.

In addition, a portion of the contact pad has a concave surface on a side of connecting to conductive lines.

As shown in, e.g., FIG. 38, this is a case in which the edge of the third resist layer 28 in the rectangular pattern 22K is brought into contact with that of the ring pattern including the second sidewalls 22a formed in the second and third openings 27a and 27b in the dummy pattern region.

Furthermore, the pattern as shown in FIG. 57 may be formed by omitting a portion of the dummy pattern in the same manner as in the example shown in FIG. 56.

### Third Example of Dummy Pattern

FIG. 58 is an example of a plan view showing the third example of the dummy pattern.

This example differs from the first and second examples in that the contact pad and dummy pattern are isolated from each other. The shape of the dummy pattern is a ring pattern and the ring pattern has a complete oblong ring shape. The shape of the dummy pattern is sometimes an ellipse or an oblong having rounded corners. For example, in the plan view shown in FIG. 38, when the third resist layer 28 in the rectangular pattern 22K is not brought into contact with the ring pattern including the second sidewalls 22a formed in the second and third openings 27a and 27b in the dummy pattern region, the second mandrel material 22 between the ring pattern and third resist layer 28 is exposed. In the step of removing the second mandrel material 22, therefore, the mandrel material 22 between the ring pattern and third resist layer 28 is removed. Consequently, the dummy pattern and contact pattern can be isolated from each other.

Furthermore, as shown in, e.g., FIG. 46, when the ring pattern is not exposed in the opening of the slit formed in the fourth resist layer 29 in the rectangular pattern 22K and extending in the second direction, the ring pattern is completely covered with the fourth resist layer 29. Accordingly, the ring pattern is not cut in the step of cutting the second mandrel material 22 and second sidewall layers 22a in the rectangular pattern 22K. As a consequence, the dummy pattern shape becomes an almost oblong ring pattern as shown in FIG. 51.

### Fourth Example of Dummy Pattern

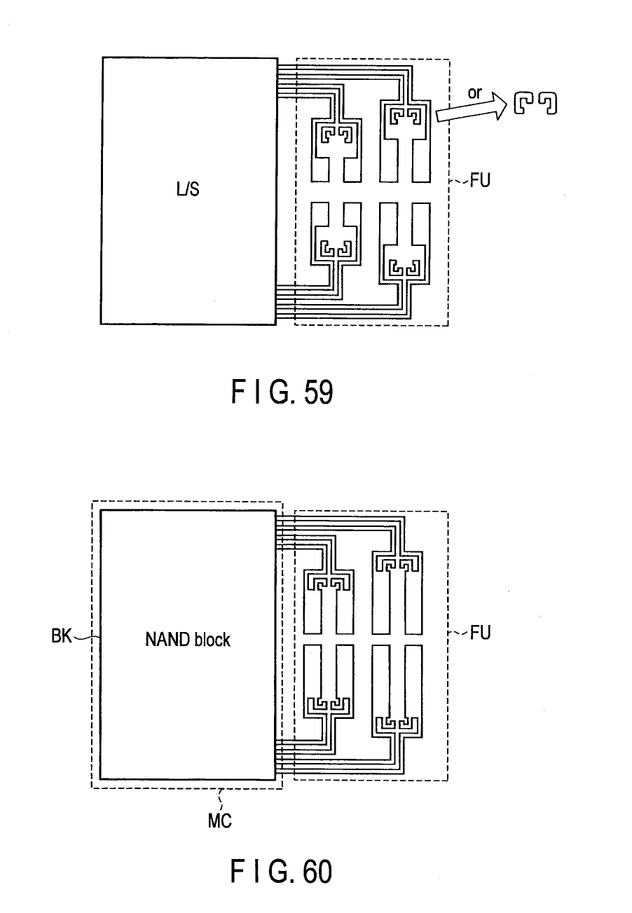

FIG. 59 is an example of a plan view showing the fourth example of the dummy pattern.

In this example, as in the third example of the dummy pattern, the contact pad and dummy pattern are isolated from each other. The shape of the dummy pattern is an oblong ring pattern and the oblong ring pattern is partially omitted. The shape of the dummy pattern can also be regarded as a semicircular shape.

The pattern as shown in FIG. 59 may be formed by isolating the dummy pattern and contact pad from each other as in the example shown in FIG. 58, and partially omitting the dummy pattern as in the examples shown in FIGS. 56 and 57.

### Application Examples

The dummy pattern and contact pad formed by the above-described manufacturing method may be applied to an interconnection pattern of a semiconductor device, e.g., an interconnection pattern of a memory cell array MC in a NAND flash memory.

For example, the hook-up region including the dummy pattern and contact pad explained in the embodiment corresponds to a word line extraction region forming a NAND block in the memory cell array MC.

FIG. 60 is an example of a view showing interconnection patterns of the word line extraction region.

This is an example in which the patterns in the hook-up region FU of the above-described embodiment exist on only one side of the memory cell array MC, and correspond to one NAND block BK.

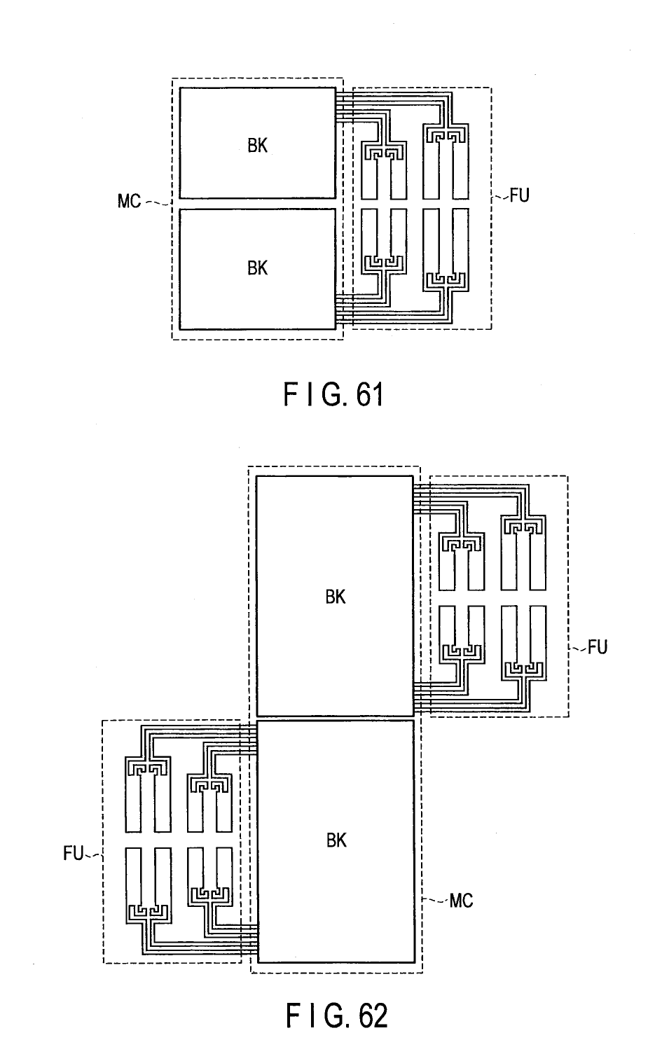

FIG. 61 is an example of a view showing interconnection patterns in the word line extraction region.

This is an example in which the patterns in the hook-up region FU of the above-described embodiment exist on only one side of the memory cell array MC, and correspond to two NAND blocks BK.

FIG. 62 is an example of a view showing interconnection patterns of the word line extraction region.

This is an example in which the patterns in the hook-up region FU of the above-described embodiment exist on both sides of the memory cell array MC, and one hook-up region FU corresponds to one NAND block BK.

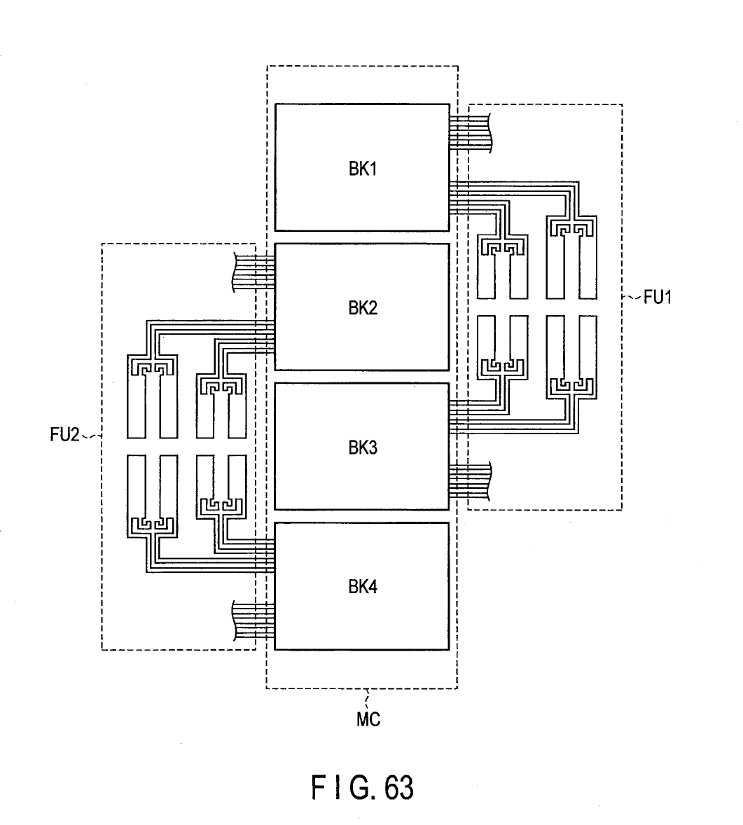

FIG. 63 is an example of a view showing interconnection patterns in the word line extraction region.

This is an example in which the patterns in the hook-up region FU of the above-described embodiment exist on both sides of the memory cell array MC, and one hook-up region FU corresponds to one NAND block BK.

Unlike in FIG. 62, however, the hook-up region FU includes a hook-up region FU1 corresponding to odd-numbered NAND blocks BK1 and BK3, and a hook-up region FU2 corresponding to even-numbered NAND blocks BK2 and BK4.

A NAND flash memory will now be explained.

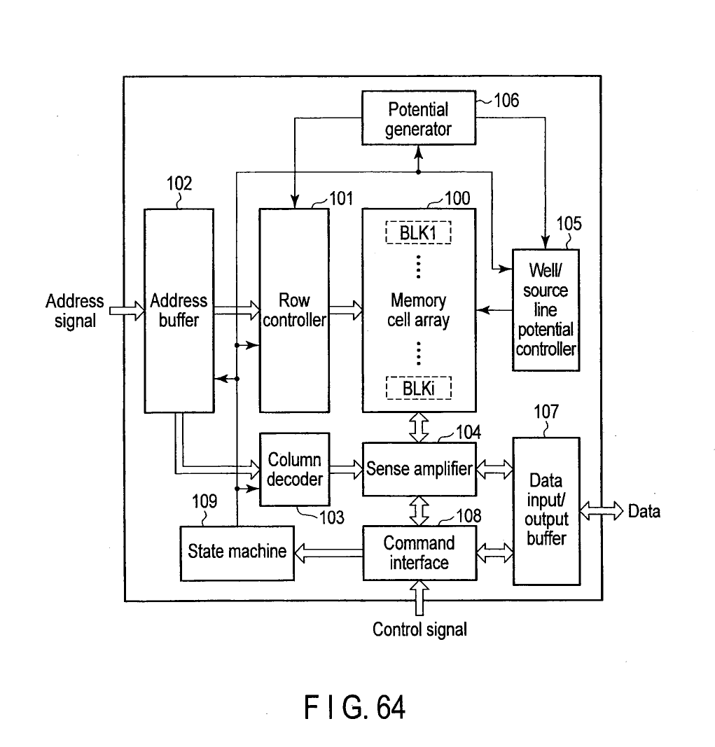

FIG. 64 is an example of a block diagram showing the main parts of the NAND flash memory.

A memory cell array 100 includes a plurality of blocks BLK1, . . . , BLKi.

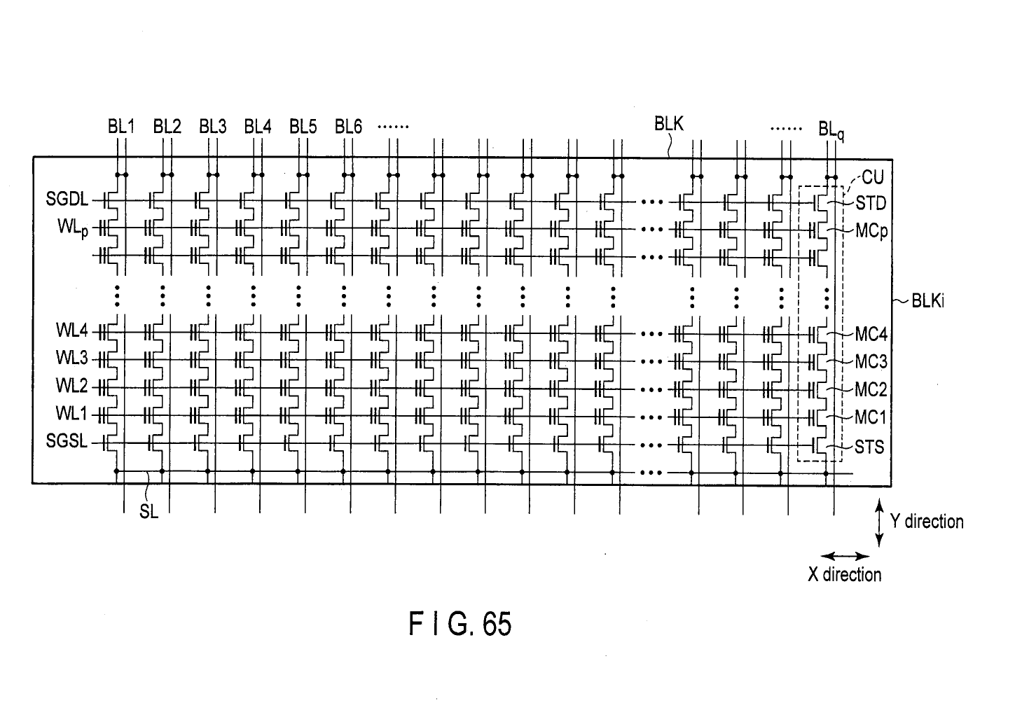

FIG. 65 is an example of an equivalent circuit diagram of one block BLKi.

One block BLKi includes a plurality of memory cell units CU arranged in the X direction (row direction). For example, q memory cell units CU are formed in one block BLKi.

One memory cell unit CU includes a memory cell string formed by a plurality of (e.g., p) memory cells MC1 to MCp, a first select transistor STS (to be referred to as a source-side select transistor hereinafter) connected to one end of the memory cell string, and a second select transistor STD (to be referred to as a drain-side select transistor hereinafter) connected to the other end of the memory cell string. In the memory cell string, the current paths of the memory cells MC1 to MCp are connected in series along the Y direction (column direction).

A source line SL is connected to one end (the source side) of the memory cell unit CU, i.e., one end of the current path of the source-side select transistor STS. Also, a bit line BL is connected to the other end (the drain side) of the memory cell unit CU, i.e., one end of the current path of the drain-side select transistor STD.

Note that the number of memory cells forming one memory cell unit CU need only be two or more, e.g., 16, 32, or 64 or more. In the following description, the memory cells MC1 to MCp will be referred to as memory cells MC if it is unnecessary to distinguish between them. Also, the source-side select transistor STD and drain-side select transistor STS will be referred to as select transistors ST if it is unnecessary to distinguish between them.

The memory cell MC is a field effect transistor having a stack gate structure including a charge storage layer capable of holding electric charge. In the memory cell MC, the threshold value of the transistor changes in accordance with the charge amount in the charge storage layer. In the memory cell MC, data to be stored is associated with the threshold voltage of the transistor.

The source and drain of two memory cells MC adjacent to each other in the Y direction are connected. Consequently, the current paths of the memory cells MC are connected in series, thereby forming the memory cell string.

The drain of the source-side select transistor STS is connected to the source of the memory cell MC1. The source of the source-side select transistor STS is connected to the source line SL. The source of the drain-side select transistor STD is connected to the drain of the memory cell MCp. The drain of the drain-side select transistor STD is connected to one bit line BLq. The number of bit lines BL1 to BLq allocated to the block BLKi is the same as that of memory cell units CU in the block BLKi.

Word lines WL1 to WLp run in the X direction, and are connected to the gates of a plurality of memory cells MC arranged along the X direction. In one memory cell unit CU, the number of word lines WL1 to WLp is the same as that (p) of memory cells in one memory cell string.

A drain-side select gate line SGDL runs in the X direction, and is connected to the gates of a plurality of drain-side select transistors STD arranged along the X direction. A source-side select gate line SGSL runs in the X direction, and is connected to the gates of a plurality of source-side select transistors STS arranged along the X direction.

In the following description, the word lines WL1 to WLp will be referred to as word lines WL if it is unnecessary to distinguish between them, and the bit lines BL1 to BLq will be referred to as bit lines BL if it is unnecessary to distinguish between them. Also, if it is unnecessary to distinguish between the source-side select gate line SGSL and drain-side select gate line SGDL, they will be referred to as select gate lines SGL.

A row controller (e.g., a word line driver) 101 controls rows of the memory cell array 100. Based on an address signal from an address buffer 102, the row controller 101 drives the word line WL in order to access a selected memory cell.

A column decoder 103 selects a column of the memory cell array 100 based on an address signal from the address buffer 102, and drives a selected bit line BL.

A sense amplifier 104 senses and amplifies the potential fluctuation of the bit line BL. Also, the sense amplifier 104 temporarily holds data read from the memory cell array 100 and data to be written to the memory cell array 100.

A well/source line potential controller 105 controls the potential of a well region and the potential of the source line SL in the memory cell array 100.

A potential generator 106 generates a voltage to be applied to the word line WL when writing (programming), reading, and erasing data. The potential generator 106 also generates a potential to be applied to the select gate line SGL, the source line SL, and the well region in a semiconductor substrate. The potential generated by the potential generator 106 is input to the row controller 101, and applied to a selected word line WL, unselected word lines WL, and the select gate line SGL.

A data input/output buffer 107 functions as a data input/output interface. The data input/output buffer 107 temporarily holds externally input data. The data input/output buffer 107 temporarily holds data output from the memory cell array 100, and outputs the held data outside at a predetermined timing.

A command interface 108 determines whether data input to the data input/output buffer 107 is command data (a command signal). If the data input to the data input/output buffer 107 contains command data, the command interface 108 transfers the command data to a state machine 109.

The state machine 109 controls the operation of each circuit in the flash memory in accordance with an external request.

Even in the NAND flash memory described above, a shortcircuit and approach of adjacent lines in the hook-up region of the word lines WL can be eliminated by forming the dummy patterns according to this embodiment.

That is, even when the word lines WL have a line-and-space pattern having a width smaller than the exposure limit, the reliability of the semiconductor device does not suffer.

### CONCLUSION

As described above, the embodiment can prevent a shortcircuit and approach of adjacent lines.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductive line and a second conductive line including a first extension region in which the first conductive line and the second conductive line extend parallel to each other in a first direction, and a bend region in which the first conductive line and the second conductive line bend in opposite directions with respect to the first direction at one end of the first extension region;
a first dummy pattern and a second dummy pattern arranged on extension regions beyond the bend region of the first conductive line and the second conductive line extending to the first direction in the first extension region, respectively;
a first contact pad formed beyond the bend region in the first direction, and connected to the first conductive line; and
a second contact pad formed beyond the bend region in the first direction, and connected to the second conductive line.

2. The device of claim 1, wherein
the first conductive line and the second conductive line further include a second extension region in which the first conductive line and the second conductive line extend parallel to each other, between the bend region and the first contact pad and second contact pad,
each of the first conductive line and the second conductive line in the second extension region is connected to one end, on a side opposite to a side of the first extension region, of a corresponding one of the first conductive line and the second conductive line in the bend region, and
each of a space between the first conductive line in the second extension region and the first dummy pattern and a space between the second conductive line in the second extension region and the second dummy pattern is not more than 100 nm.

3. The device of claim 1, wherein
the first conductive line and the second conductive line further include a second extension region in which the first conductive line and the second conductive line extend parallel to each other, between the bend region and the first contact pad and second contact pad,
each of the first conductive line and the second conductive line in the second extension region is connected to one end, on a side opposite to a side of the first extension region, of a corresponding one of the first conductive line and the second conductive line in the bend region, and
each of the first dummy pattern and the second dummy pattern has a first portion, a second portion, and a third portion, the first portion extending in the first direction and formed on an extension region of a corresponding one of the first conductive line and the second conductive line extending to the first direction in the first extension region, the second portion having one end in contact with the first portion and extending in a second direction crossing to the first direction, and the third portion having one end in contact with the second portion and extending in the first direction.

4. The device of claim 1, wherein directions in which the first conductive line and the second conductive line extend in the first extension region and the second extension region are the same.

5. The device of claim 1, wherein in the bend region, each of the first conductive line and the second conductive line bend at an angle of 90° or more.

6. The device of claim 1, wherein the first dummy pattern and the second dummy pattern are symmetrically arranged in the first direction.

7. The device of claim 1, wherein a space between the first conductive line and the second conductive line in the first extension region is equal to a space between the first dummy pattern and the second dummy pattern.

8. The device of claim 1, wherein the first conductive line and the second conductive line are formed by using sidewall processing not less than twice.

9. The device of claim 1, wherein a width of the first contact pad and the second contact pad is larger than a width of the first conductive line and the second conductive line.

10. The device of claim 1, wherein the first conductive line and the second conductive line in the bend region are not in contact with the first dummy pattern and the second dummy pattern.

11. The device of claim 1, further comprising:
a first word line extending in a second direction crossing to the first direction and connected to the first conductive line;
a second word line extending in the second direction, connected to the second conductive line, and adjacent to the first word line;
a third word line extending in the second direction and adjacent to the second word line; and
a fourth word line extending in the second direction and adjacent to the third word line,
wherein the first word line, the second word line, the third word line, and the fourth word line are arranged in order in the first direction, and
letting L1 be a width of the first word line, L2 be a width of the second word line, L3 be a width of the third word line, and L4 be a width of the fourth word line, L1>L2>L3>L4.

12. The device of claim 1, wherein the first dummy pattern and the first contact pad are in contact with each other, the second dummy pattern and the second contact pad are in contact with each other, and the first dummy pattern and the second dummy pattern have one of a partially omitted oblong ring shape, an oblong ring shape having rounded corners, and a semicircular shape.

13. The device of claim 1, wherein the first dummy pattern and the first contact pad are in contact with each other, the second dummy pattern and the second contact pad are in contact with each other, the first dummy pattern and the second dummy pattern have one of a partially omitted oblong ring shape, an oblong ring shape having rounded corners, and a semicircular shape, and the first contact pad and the second contact pad have a concave surface.

14. The device of claim 1, wherein the first dummy pattern and the first contact pad are separated from each other, the second dummy pattern and the second contact pad are separated from each other, and the first dummy pattern and the second dummy pattern have one of an oblong shape, an elliptical shape, and an oblong ring shape having rounded corners.

15. The device of claim 1, wherein the first dummy pattern and the first contact pad are separated from each other, the second dummy pattern and the second contact pad are separated from each other, and the first dummy pattern and the second dummy pattern have one of a partially omitted oblong ring shape, an oblong ring shape having rounded corners, and a semicircular shape.

16. The device of claim 1, wherein a hook-up region includes the first dummy pattern, the second dummy pattern, the first contact pad, and the second contact pad, and the hook-up region is disposed one side of a NAND block.
